(19) United States
(12) Patent Application Publication
(10) Pub. No.: US 2025/0338760 A1
(43) Pub. Date: Oct. 30, 2025

(54) COLOR CONVERSION SUBSTRATE, DISPLAY DEVICE INCLUDING THE COLOR CONVERSION SUBSTRATE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-Si (KR)

(72) Inventor: SEON UK LEE, Yongin-si (KR)

(21) Appl. No.: 19/007,552

(22) Filed: Jan. 2, 2025

(30) Foreign Application Priority Data
Apr. 25, 2024 (KR) 10-2024-0055426

(51) Int. Cl. H10K 59/80; H10K 59/12; H10K 59/122; H10K 59/38

(52) U.S. Cl. CPC H10K 59/878; H10K 59/1201; H10K 59/122; H10K 59/38; H10K 59/877

(57) ABSTRACT

A color conversion substrate is disclosed that includes a first color conversion pattern overlapping a first emission area, a second color conversion pattern overlapping a second emission area, a first outer wall accommodating the first color conversion pattern and including scattering particles, a second outer wall accommodating the second color conversion pattern and including the scattering particles, and an inner wall interposed between the first outer wall and the second outer wall.

This application claims priority to Korean Patent Application No. 10-2024-0055426,filed on Apr. 25, 2024, and all the benefits accruing therefrom under 35 U.S.C. § 119, the content of which in its entirety is herein incorporated by reference.

### BACKGROUND

### Field

The present inventive concept relates to a color conversion substrate, a display device including the color conversion substrate, and a method of manufacturing the display device.

### Discussion of the Background

A display device includes an emission layer and a plurality of color conversion patterns. Light is emitted from the emission layer, and the color conversion patterns convert the color of the light.

The color conversion patterns may include quantum dots and are divided into a red color conversion pattern, a green color conversion pattern, and a scattering pattern (or, blue color conversion pattern). The red color conversion pattern forms part of a red pixel, the green color conversion pattern forms part of a green pixel, and the scattering pattern forms part of a blue pixel.

### SUMMARY

Embodiments provide a color conversion substrate.

Embodiments provide a display device including the color conversion substrate.

Embodiments provide a method of manufacturing the display device.

Embodiments provide an electronic device including the display device.

A color conversion substrate according to an embodiment may include an upper substrate divided into a first emission area, a second emission area adjacent to the first emission area, and a non-emission area located between the first emission area and the second emission area, a first color conversion pattern disposed on the upper substrate and overlapping the first emission area, a second color conversion pattern disposed on the upper substrate and overlapping the second emission area, a first outer wall accommodating the first color conversion pattern, overlapping the non-emission area, and including scattering particles, a second outer wall accommodating the second color conversion pattern, overlapping the non-emission area, and including the scattering particles, and an inner wall interposed between the first outer wall and the second outer wall.

In an embodiment, the first outer wall and the second outer wall may scatter light, and the inner wall may block light.

In an embodiment, the first outer wall and the second outer wall may support the inner wall.

In an embodiment, the inner wall may overlap the non-emission area.

In an embodiment, the color conversion substrate may further include a third color conversion pattern disposed on the upper substrate, overlapping a third emission area adjacent to the second emission area, and including the scattering particles.

In an embodiment, the first outer wall and the second outer wall may include a same material as the third color conversion pattern.

In an embodiment, the color conversion substate may further include a column spacer disposed on the third color conversion pattern and including a same material as the inner wall.

In an embodiment, the color conversion substate may further include a reflective pattern interposed between the first outer wall and the inner wall.

In an embodiment, the reflective pattern may contact the first outer wall and the inner wall.

In an embodiment, a boundary of the reflective pattern may coincide with a boundary of the inner wall.

In an embodiment, the reflective pattern may reflect light.

In an embodiment, the reflective pattern may include metal.

In an embodiment, the reflective pattern may support the inner wall.

In an embodiment, the reflective pattern may be further interposed between the second outer wall and the inner wall.

A display device according to an embodiment may include a lower substrate divided into a first emission area, a second emission area adjacent to the first emission area, and a non-emission area located between the first emission area and the second emission area, a first color conversion pattern disposed on the lower substrate and overlapping the first emission area, a second color conversion pattern disposed on the lower substrate and overlapping the second emission area, a first outer wall accommodating the first color conversion pattern, overlapping the non-emission area, and including scattering particles, a second outer wall accommodating the second color conversion pattern, overlapping the non-emission area, and including the scattering particles, and an inner wall interposed between the first outer wall and the second outer wall.

In an embodiment, the display device may further include a first pixel electrode disposed between the lower substrate and the first color conversion pattern and overlapping the first color conversion pattern, a second pixel electrode disposed between the lower substrate and the second color conversion pattern and overlapping the second color conversion pattern, and an emission layer disposed on the first pixel electrode and the second pixel electrode.

In an embodiment, the display device may further include a pixel defining layer disposed between the lower substrate and the inner wall and overlapping the inner wall.

In an embodiment, the first outer wall and the second outer wall may scatter light, and the inner wall may block light.

In an embodiment, the first outer wall and the second outer wall may support the inner wall.

In an embodiment, the inner wall may overlap the non-emission area.

In an embodiment, the display device may further include a third color conversion pattern disposed on the lower substrate, overlapping a third emission area adjacent to the second emission area, and including the scattering particles.

In an embodiment, the first outer wall and the second outer wall may include a same material as the third color conversion pattern.

In an embodiment, the display device may further include a column spacer disposed on the third color conversion pattern and including a same material as the inner wall.

In an embodiment, the display device may further include a reflective pattern interposed between the first outer wall and the inner wall.

In an embodiment, the reflective pattern may contact the first outer wall and the inner wall.

In an embodiment, a boundary of the reflective pattern may coincide with a boundary of the inner wall.

In an embodiment, the reflective pattern may reflect light.

In an embodiment, the reflective pattern may include metal.

In an embodiment, the reflective pattern may support the inner wall.

In an embodiment, the reflective pattern may be further interposed between the second outer wall and the inner wall.

A method of manufacturing a display device according to an embodiment may include providing an upper substrate divided into a first emission area, a second emission area adjacent to the first emission area, and a non-emission area located between the first emission area and the second emission area, forming a first outer wall on the upper substrate, the first outer wall overlaps the non-emission area and including scattering particles, forming a second outer wall on the upper substrate, the second outer wall overlaps the non-emission area and including the scattering particles, forming an inner wall interposed between the first outer wall and the second outer wall, forming a first conversion pattern accommodated in the first outer wall and overlapping the first emission area, and forming a second conversion pattern accommodated in the second outer wall and overlapping the second emission area.

In an embodiment, the first outer wall and the second outer wall may be formed together.

In an embodiment, the method may further include forming a third color conversion pattern on the upper substrate, and the third color conversion pattern may overlap a third emission area adjacent to the second emission area and including the scattering particles

In an embodiment, the first outer wall, the second outer wall, and the third color conversion pattern may be formed together.

In an embodiment, the method may further include forming a column spacer on the third color conversion pattern, and the column spacer may include a same material as the inner wall.

In an embodiment, the inner wall and the column spacer may be formed together.

In an embodiment, the method may further include forming a reflective pattern interposed between the first outer wall and the inner wall.

In an embodiment, the reflective pattern may contact the first outer wall and the inner wall.

In an embodiment, the forming the reflective pattern may include forming a preliminary reflective pattern covering the first outer wall, and etching the preliminary reflective pattern using the inner wall as a mask.

An electronic device according to an embodiment may include a display device and a power supply configured to provide power to the display device. The display device may include a lower substrate divided into a first emission area, a second emission area adjacent to the first emission area, and a non-emission area located between the first emission area and the second emission area, a first color conversion pattern disposed on the lower substrate and overlapping the first emission area, a second color conversion pattern disposed on the lower substrate and overlapping the second emission area, a first outer wall accommodating the first color conversion pattern, overlapping the non-emission area, and including scattering particles, a second outer wall accommodating the second color conversion pattern, overlapping the non-emission area, and including the scattering particles, and an inner wall interposed between the first outer wall and the second outer wall.

Therefore, a display device according to embodiments may include a color conversion substrate. The color conversion substrate may include a first outer wall, a second outer wall, a reflective pattern, and an inner wall.

A first color conversion pattern may be accommodated in the first outer wall, and a second color conversion pattern may be accommodated in the second outer wall. The inner wall may be disposed between the first and second outer walls, and the reflective pattern may be interposed between the first outer wall (or, the second outer wall) and the inner wall.

The first and second outer walls may support the inner wall and may fix the inner wall. Accordingly, the reliability of the display device can be improved.

In addition, the first and second outer walls may include scattering particles, and the reflective pattern may reflect light. Accordingly, the aperture ratio of the display device can be increased.

In addition, the inner wall can block light. Accordingly, the inner wall can suppress external light reflection and prevent color mixing. Accordingly, color reproducibility of the display device can be improved.

In the method of manufacturing a display device according to embodiments, the first outer wall and the second outer wall may be formed together with the third color conversion pattern. Accordingly, in the process of forming the first outer wall and the second outer wall, an additional mask may not be required.

In addition, by patterning the preliminary inner wall, the inner wall and the column spacer may be formed together. Accordingly, in the process of forming the inner wall, an additional mask may not be required.

In addition, the reflective pattern and the metal pattern may be formed by using the inner wall and the column spacer as a mask. Accordingly, in the process of forming the reflective pattern and the metal pattern, an additional mask may not be required.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a perspective view illustrating a display device according to an embodiment.

FIG. 2 is a block diagram illustrating the display device of FIG. 1.

FIG. 3 is a circuit diagram illustrating a pixel included in the display device of FIG. 2.

FIG. 4 is a cross-sectional view illustrating the display device of FIG. 1.

FIG. 5 is a cross-sectional view illustrating an emission substrate included in the display device of FIG. 4.

FIG. 6 is a cross-sectional view illustrating a color conversion substrate included in the display device of FIG. 4.

FIG. 7 is an enlarged view of area A of FIG. 6.

FIGS. 8 to 22 are diagrams illustrating a method of manufacturing the display device of FIG. 4.

FIG. 23 is a cross-sectional view illustrating a display device according to an embodiment.

FIG. 24 is a cross-sectional view illustrating an emission substrate included in the display device of FIG. 23.

FIG. 25 is a cross-sectional view illustrating a color conversion substrate included in the display device of FIG. 23.

FIG. 26 is a block diagram illustrating an electronic device according to an embodiment.

FIG. 27 is a schematic diagram of electronic devices.

### DETAILED DESCRIPTION

Illustrative, non-limiting embodiments will be more clearly understood from the following detailed description in conjunction with the accompanying drawings.

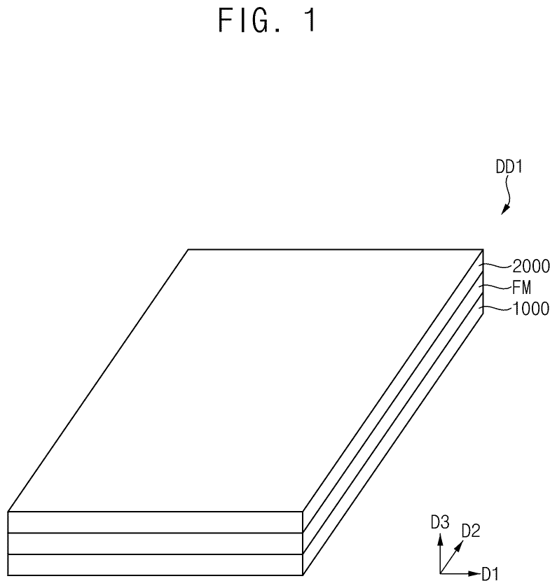

FIG. 1 is a perspective view illustrating a display device according to an embodiment.

Referring to FIG. 1, a display device DD1 according to an embodiment may include an emission substrate 1000, a filler FM, and a color conversion substrate 2000. The display device DD1 may have a display surface composed of a first direction D1 and a second direction D2 intersecting the first direction D1, and may have a thickness in a third direction D3 intersecting the first and second directions D1 and D2.

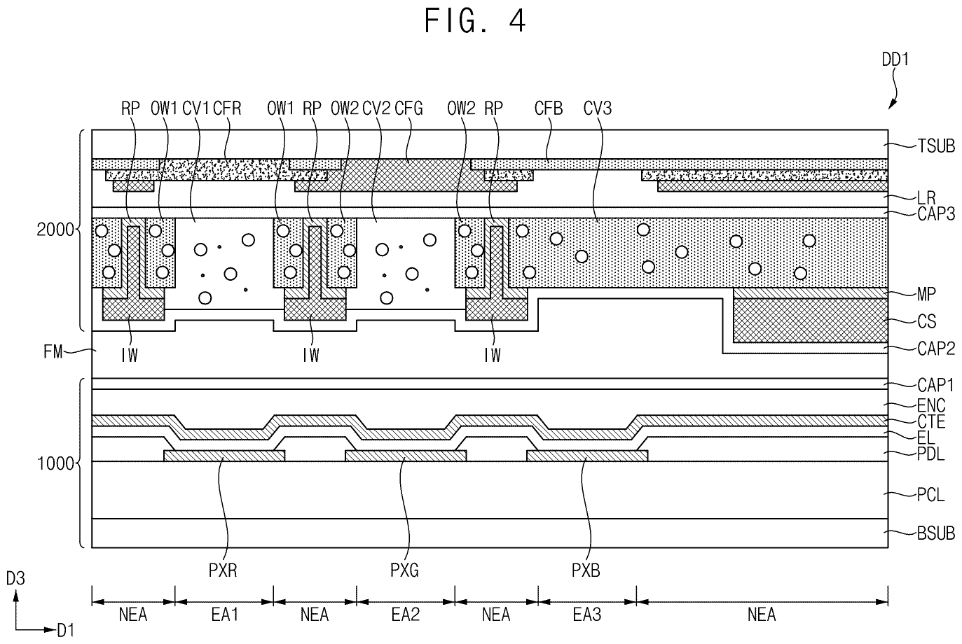

The emission substrate 1000 may generate and emit light. In an embodiment, the emission substrate 1000 may include a pixel circuit layer (e.g., the pixel circuit layer PCL in FIG. 4) and an emission layer (e.g., the emission layer EL in FIG. 4). The pixel circuit layer may generate a driving current, and the emission layer may emit light based on the driving current.

The color conversion substrate 2000 may be disposed on the emission substrate 1000. In an embodiment, the color conversion substrate 2000 may convert the color of light emitted from the emission substrate 1000. Accordingly, color reproducibility of the display device DD1 may be improved.

The filler FM may be interposed between the emission substrate 1000 and the color conversion substrate 2000. In an embodiment, the filler FM may improve the reliability of the display device DD1 and refract light.

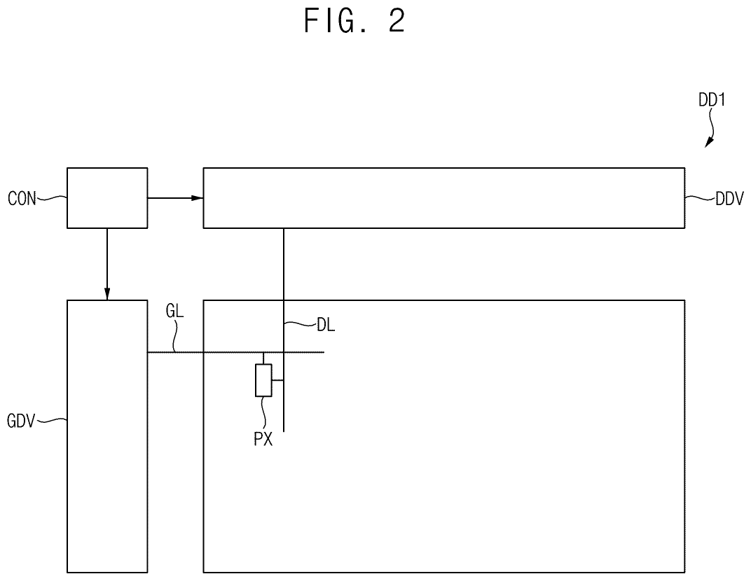

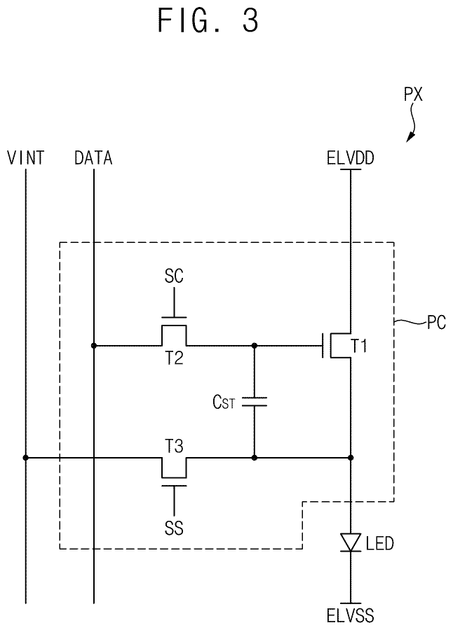

FIG. 2 is a block diagram illustrating the display device of FIG. 1. FIG. 3 is a circuit diagram illustrating a pixel included in the display device of FIG. 2.

Referring to FIG. 2, the display device DD1 may include a gate driver GDV, a data driver DDV, a controller CON, and a pixel PX.

The gate driver GDV may generate a gate signal (e.g., a first gate signal SC and a second gate signal SS in FIG. 3). The gate driver GDV may sequentially provide the gate signal, and the gate signal may be transmitted to the pixel PX through a gate line GL.

The data driver DDV may generate a data voltage (e.g., the data voltage DATA in FIG. 3). The data voltage may be transmitted to the pixel PX through a data line DL.

The controller CON may be connected to an external processor (e.g., GPU, etc.) and may control the gate driver GDV and the data driver DDV. For example, the controller CON may transmit a gate control signal to the gate driver GDV and a data control signal to the data driver DDV.

The pixel PX may receive the gate signal through the gate line GL and the data voltage through the data line DL. The pixel PX may be turned on or off in response to the gate signal and may generate light corresponding to the data voltage.

Referring to FIG. 3, the pixel PX may include a pixel circuit PC and a light emitting diode LED. The light emitting diode LED may be connected to the pixel circuit PC. The pixel circuit PC may generate the driving current, and the light emitting diode LED may generate light corresponding to the driving current.

In an embodiment, the pixel circuit PC may include a first transistor T1, a second transistor T2, a third transistor T3, and a storage capacitor CST.

The first transistor T1 may include a gate terminal, a first terminal, and a second terminal. The gate terminal may be electrically connected to the second transistor T2. The first terminal may be provided with a first voltage ELVDD. The second terminal may be electrically connected to the light emitting diode LED. The first transistor T1 may generate the driving current.

The second transistor T2 may include a gate terminal, a first terminal, and a second terminal. The gate terminal may receive the first gate signal SC. The first terminal may receive the data voltage DATA. The second terminal may be electrically connected to the first transistor T1. The second transistor T2 may transmit the data voltage DATA in response to the first gate signal SC.

The third transistor T3 may include a gate terminal, a first terminal, and a second terminal. The gate terminal may receive the second gate signal SS. The first terminal may be provided with an initialization voltage VINT. The second terminal may be electrically connected to the light emitting diode LED. The third transistor T3 may transmit the initialization voltage VINT in response to the second gate signal SS.

The storage capacitor CST may include a first terminal and a second terminal. The first terminal may be electrically connected to the gate terminal of the first transistor T1. The second terminal may be electrically connected to the second terminal of the first transistor T1.

The light emitting diode LED may include a first terminal and a second terminal. The first terminal may be electrically connected to the first transistor T1. The second terminal may be provided with a second voltage ELVSS.

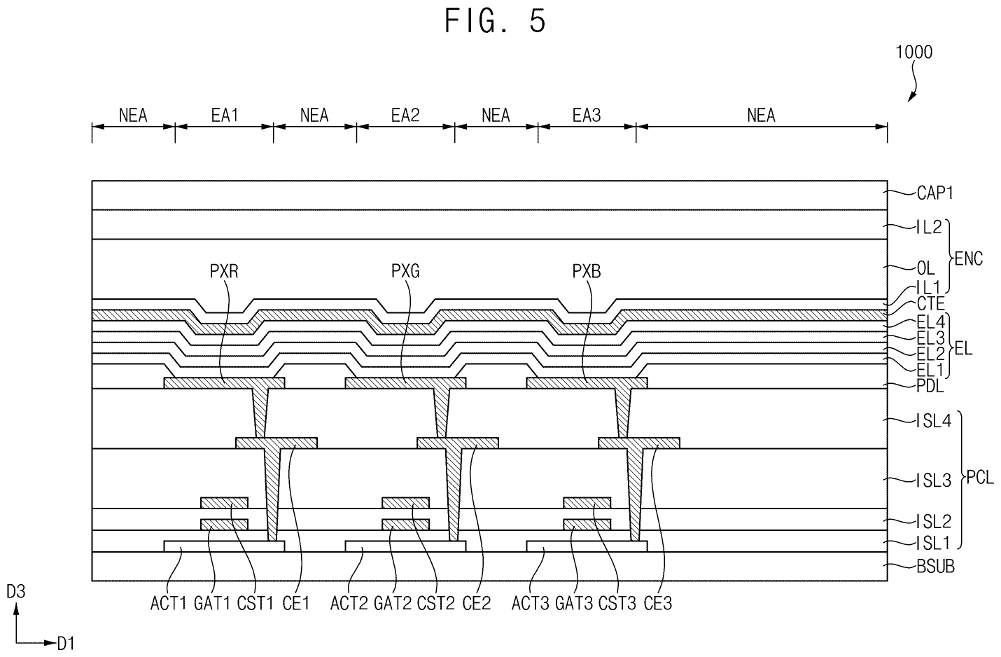

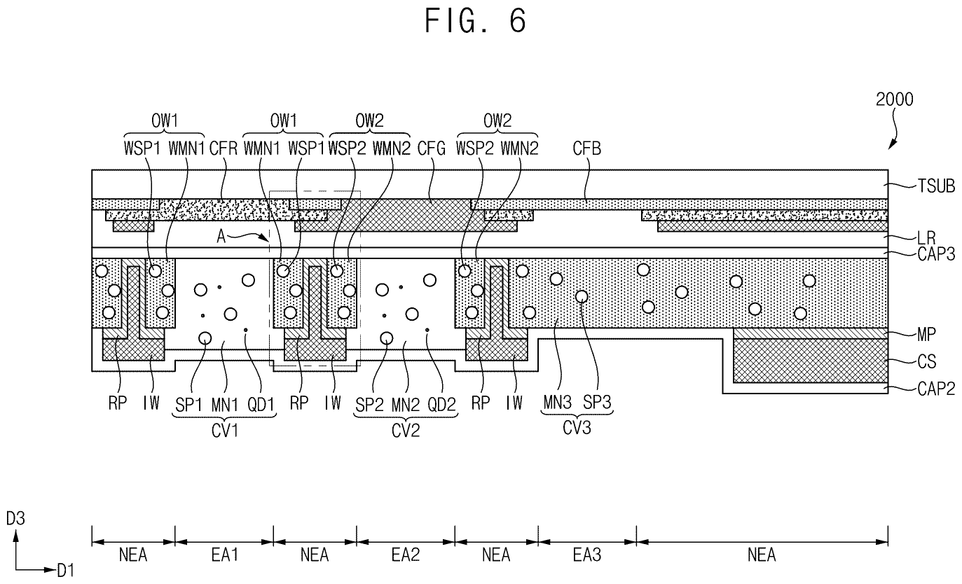

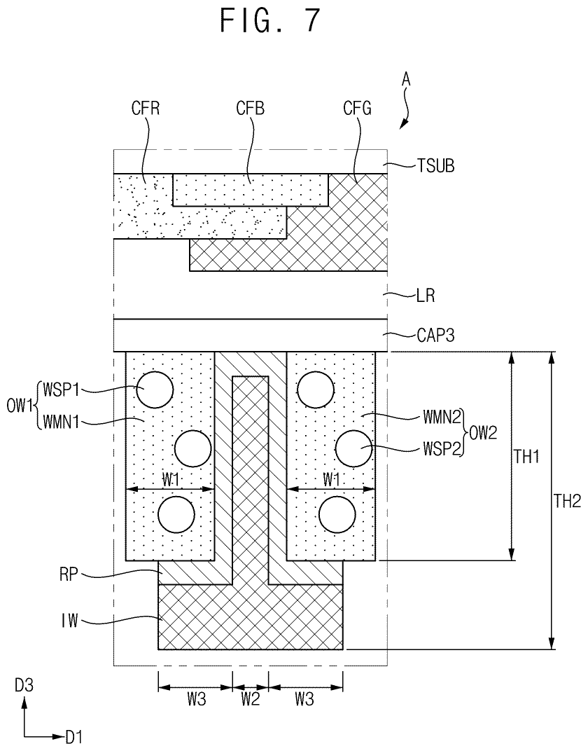

FIG. 4 is a cross-sectional view illustrating the display device of FIG. 1. FIG. 5 is a cross-sectional view illustrating an emission substrate included in the display device of FIG. 4. FIG. 6 is a cross-sectional view illustrating a color conversion substrate included in the display device of FIG. 4. FIG. 7 is an enlarged view of area A of FIG. 6.

Referring to FIG. 4, the display device DD1 may include the emission substrate 1000, the filler FM, and the color conversion substrate 2000.

In an embodiment, the display device DD1 may be divided into a first emission area EA1, a second emission area EA2, a third emission area EA3, and a non-emission area NEA. Light having a first color (e.g., red) may be emitted from the first emission area EA1, light having a second color (e.g., green) may be emitted from the second emission area EA2, light having a third color (e.g., blue) may be emitted from the third emission area EA3, and no light may be emitted from the non-emission area NEA.

In an embodiment, the second emission area EA2 may be adjacent to the first emission area EA1, the third emission area EA3 may be adjacent to the second emission area EA2, and the non-emission area NEA may be located around each of the first to third emission areas EA1, EA2, and EA3.

Referring to FIGS. 4 and 5, in an embodiment, the emission substrate 1000 may include a lower substrate BSUB, a pixel circuit layer PCL, a first pixel electrode PXR, a second pixel electrode PXG, a second pixel electrode PXG, a third pixel electrode PXB, a pixel defining layer PDL, an emission layer EL, a common electrode CTE, an encapsulation layer ENC, and a first capping layer CAP1.

In an embodiment, the pixel circuit layer PCL may include a first active pattern ACT1, a second active pattern ACT2, a third active pattern ACT3, a first insulating layer ISL1, a first gate electrode GAT1, a second gate electrode GAT2, a third gate electrode GAT3, a second insulating layer ISL2, a first capacitor electrode CST1, a second capacitor electrode CST2, a third capacitor electrode CST3, a third insulating layer ISL3, a first connection electrode CE1, a second connection electrode CE2, a third connection electrode CE3, and a fourth insulating layer ISL4.

The lower substrate BSUB may include a transparent material or an opaque material. In an embodiment, examples of materials that can be used as the lower substrate BSUB may include glass, quartz, and plastic. These can be used alone or in combination with each other.

The first active pattern ACT1 may be disposed on the lower substrate BSUB. In an embodiment, the first active pattern ACT1 may include a silicon semiconductor, an oxide semiconductor, or the like. For example, the silicon semiconductor may include amorphous silicon, polycrystalline silicon, etc. The first active pattern ACT1 may pass current or block current according to the gate signal provided to the first gate electrode GAT1.

The second active pattern ACT2 and the third active pattern ACT3 may be formed together with the first active pattern ACT1 and may include the same material as the first active pattern ACT1. Each of the second active pattern ACT2 and the third active pattern ACT3 may pass current or block current according to the gate signal provided to each of the second gate electrode GAT2 and the third gate electrode GAT3.

The first insulating layer ISL1 may be disposed on the lower substrate BSUB and may cover the first to third active patterns ACT1, ACT2, and ACT3. In an embodiment, the first insulating layer ISL1 may include an insulating material. For example, the first insulating layer ISL1 may include silicon oxide, silicon nitride, titanium oxide, tantalum oxide, etc.

The first gate electrode GAT1 may be disposed on the first insulating layer ISL1. In an embodiment, the first gate electrode GAT1 may include a metal, an alloy, a conductive metal oxide, etc. For example, the first gate electrode GAT1 may include silver (Ag), an alloy containing silver, molybdenum (Mo), an alloy containing molybdenum, aluminum (Al), an alloy containing aluminum, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The second gate electrode GAT2 and the third gate electrode GAT3 may be formed together with the first gate electrode GAT1 and may include the same material as the first gate electrode GAT1.

The second insulating layer ISL2 may be disposed on the first insulating layer ISL1 and may cover the first to third gate electrodes GAT1, GAT2, and GAT3. In an embodiment, the second insulating layer ISL2 may include an insulating material. For example, the second insulating layer ISL2 may include silicon oxide, silicon nitride, titanium oxide, tantalum oxide, etc.

The first capacitor electrode CST1 may be disposed on the second insulating layer ISL2 and may overlap the first gate electrode GAT1. In an embodiment, the first capacitor electrode CST1 may include a metal, an alloy, a conductive metal oxide, etc. For example, the first capacitor electrode CST1 may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The second capacitor electrode CST2 and the third capacitor electrode CST3 may be formed together with the first capacitor electrode CST1 and may include the same material as the first capacitor electrode CST1.

The third insulating layer ISL3 may be disposed on the second insulating layer ISL2 and may cover the first to third capacitor electrodes CST1, CST2, and CST3. In an embodiment, the third insulating layer ISL3 may include an insulating material. For example, the third insulating layer ISL3 may include silicon oxide, silicon nitride, titanium oxide, tantalum oxide, etc.

The first connection electrode CE1 may be disposed on the third insulating layer ISL3 and may be connected to the first active pattern ACT1. In an embodiment, the first connection electrode CE1 may include a metal, an alloy, a conductive metal oxide, etc. For example, the first connection electrode CE1 may include silver (Ag), an alloy containing silver, molybdenum (Mo), an alloy containing molybdenum, aluminum (Al), an alloy containing aluminum, aluminum nitride (AIN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The second connection electrode CE2 and the third connection electrode CE3 may be formed together with the first connection electrode CE1 and may include the same material as the first connection electrode CE1. The second connection electrode CE2 and the third connection electrode CE3 may be connected to the second active pattern ACT2 and the third active pattern ACT3, respectively.

The fourth insulating layer ISL4 may be disposed on the third insulating layer ISL3 and may at least partially cover the first to third connection electrodes CE1, CE2, and CE3. In an embodiment, the fourth insulating layer ISL4 may include an insulating material. For example, the fourth insulating layer ISL4 may include photoresist, polyacrylic resin, polyimide resin, acrylic resin, etc.

The first pixel electrode PXR may be disposed on the fourth insulating layer ISL4 and may be connected to the first connection electrode CE1. In an embodiment, the first pixel electrode PXR may include a metal, an alloy, a conductive metal oxide, etc. For example, the first pixel electrode PXR may include silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The second pixel electrode PXG and the third pixel electrode PXB may be formed together with the first pixel electrode PXR and may include the same material as the first pixel electrode PXR. The second pixel electrode PXG and the third pixel electrode PXB may be connected to the second connection electrode CE2 and the third connection electrode CE3, respectively.

The pixel defining layer PDL may be disposed on the fourth insulating layer ISL4, and openings extending to pixel electrodes may be formed in the pixel defining layer PDL. For example, the pixel defining layer PDL may be made of organic materials such as polyimide resin (e.g., photosensitive polyimide resin (PSPI)), photoresist, polyacrylic resin, and acrylic resin, or may be made of inorganic materials such as silicon oxide and silicon nitride.

The emission layer EL may be disposed on the first to third pixel electrodes PXR, PXG, and PXB. In an embodiment, the emission layer EL may include a first blue emission layer EL1, a second blue emission layer EL2, a third blue emission layer EL3, and a green emission layer EL4.

In an embodiment, the first blue emission layer EL1 may be entirely disposed on the first pixel electrode PXR, the second pixel electrode PXG, the third pixel electrode PXB, and the pixel defining layer PDL. For example, the first blue emission layer EL1 may include an organic material that emits blue light.

In an embodiment, the second blue emission layer EL2 may be disposed on the first blue emission layer EL1. For example, the second blue emission layer EL2 may include an organic material that emits blue light.

In an embodiment, the third blue emission layer EL3 may be disposed on the second blue emission layer EL2. For example, the third blue emission layer EL3 may include an organic material that emits blue light.

In an embodiment, the green emission layer EL4 may be disposed on the third blue emission layer EL3. For example, the green emission layer EL4 may include an organic material that emits green light.

The common electrode CTE may be disposed on the green emission layer EL4. In an embodiment, the common electrode CTE may be formed of metal, alloy, conductive metal oxide, transparent conductive material, etc.

The encapsulation layer ENC may be disposed on the common electrode CTE. The encapsulation layer ENC may protect the emission layer EL. In an embodiment, the encapsulation layer ENC may include a first inorganic layer IL1, an organic layer OL, and a second inorganic layer IL2.

The first capping layer CAP1 may be disposed on the encapsulation layer ENC. The first capping layer CAP1 may protect the encapsulation layer ENC. In an embodiment, the first capping layer CAP1 may include an inorganic material. For example, the first capping layer CAP1 may include silicon oxide, silicon nitride, titanium oxide, tantalum oxide, etc. In another embodiment, the first capping layer CAP1 may include an organic material.

The filler FM may be disposed on the first capping layer CAP1. In an embodiment, the filler FM may include an organic material such as urethane-based resin, epoxy-based resin, or acrylic resin.

Referring to FIGS. 4 and 6, the color conversion substrate 2000 may include an upper substrate TSUB, a first color filter CFR, a second color filter CFG, a third color filter CFB, a refractive layer LR, a third capping layer CAP3, a first outer wall OW1, a second outer wall OW2, a third color conversion pattern CV3, a reflective pattern RP, a metal pattern MP, an inner wall IW, a column spacer CS, a first color conversion pattern CV1, a second color conversion pattern CV2, and a second capping layer CAP2.

The first outer wall OW1 may overlap the non-emission area NEA. For example, the first outer wall OW1 may overlap the pixel defining layer PDL. In addition, the first outer wall OW1 may be formed to surround the first emission area EA1.

In an embodiment, the first outer wall OW1 may include a first wall monomer WMN1 and first wall scattering particles WSP1. The first wall scattering particles WSP1 may be dispersed in the first wall monomer WMN1.

In an embodiment, the first wall monomer WMN1 may include an epoxy-based monomer, an ester-based monomer, etc.

The first wall scattering particles WSP1 may scatter light. In an embodiment, the first wall scattering particles WSP1 may include titanium dioxide (TiO₂) particles, zinc oxide (ZnO) particles, aluminum oxide (Al₂O₃) particles, silicon oxide (SiO₂) particles, hollow silica particles, etc.

The second outer wall OW2 may overlap the non-emission area NEA. For example, the second outer wall OW2 may overlap the pixel defining layer PDL. In addition, the second outer wall OW2 may be formed to surround the second emission area EA2.

In an embodiment, the second outer wall OW2 may include a second wall monomer WMN2 and second barrier scattering particles WSP2. The second wall scattering particles WSP2 may be dispersed in the second wall monomer WMN2.

In an embodiment, the second wall monomer WMN2 may include an epoxy-based monomer, an ester-based monomer, etc.

The second wall scattering particles WSP2 may scatter light. In an embodiment, the second wall scattering particles WSP2 may include titanium dioxide (TiO₂) particles, zinc oxide (ZnO) particles, aluminum oxide (Al₂O₃) particles, silicon oxide (SiO₂) particles, hollow silica particles, etc.

In an embodiment, the second outer wall OW2 may be formed of the same material as the first outer wall OW1. In detail, the second wall monomer WMN2 may be the same material as the first wall monomer WMN1, and the second wall scattering particles WSP2 may be the same material as the first wall scattering particles WSP1.

The third color conversion pattern CV3 may overlap the third emission area EA3 and the non-emission area NEA. For example, the third color conversion pattern CV3 may overlap the third pixel electrode PXB and the pixel defining layer PDL.

In an embodiment, the third color conversion pattern CV3 may include a third monomer MN3 and third scattering particles SP3. The third scattering particles SP3 may be dispersed in the third monomer MN3.

In an embodiment, the third monomer MN3 may include an epoxy-based monomer, an ester-based monomer, etc.

The third scattering particles SP3 may scatter light. In an embodiment, the third scattering particles SP3 may include titanium dioxide (TiO₂) particles, zinc oxide (ZnO) particles, aluminum oxide (Al₂O₃) particles, silicon oxide (SiO₂) particles, hollow silica particles, etc.

In the embodiment shown in FIGS. 4 and 6, the third color conversion pattern CV3 does not include quantum dots. In another embodiment, the third color conversion pattern CV3 may include quantum dots at least in the third emission area EA3. For example, one or more of emission layers of the first to third pixels PXR, PXG, and PXB may emit ultraviolet light so that the quantum dots in the third color pattern may convert the ultraviolet light to blue light.

In an embodiment, the first outer wall OW1 and the second outer wall OW2 may be formed of the same material as the third color conversion pattern CV3. In detail, the first wall monomer WMN1 and the second wall monomer WMN2 may be the same material as the third monomer MN3, and the first wall scattering particles WSP1 and the second wall scattering particles WSP2 may be the same material as the third scattering particles SP3.

In an embodiment, the first outer wall OW1 and the second outer wall OW2 may be formed together with the third color conversion pattern CV3. Accordingly, the thickness of the first external partition OW1 and the thickness of the second external partition OW2 may be substantially the same as the thickness of the third color conversion pattern CV3.

The inner wall IW may overlap the non-emission area NEA. For example, the inner wall IW may overlap the pixel defining layer PDL. In addition, the inner wall IW may be formed to surround the first emission area EA1 and the second emission area EA2.

In an embodiment, the inner wall IW may be interposed between the first outer wall OW1 and the second outer wall OW2. Accordingly, the first outer wall OW1 and the second outer wall OW2 may support the inner wall IW.

In an embodiment, the inner wall IW may include a light blocking material. For example, the inner wall IW may include a dye or pigment having light blocking properties. Accordingly, the inner wall IW may suppress external light reflection and prevent color mixing.

The column spacer CS may overlap the non-emission area NEA. For example, the column spacer CS may overlap the third color conversion pattern CV3 and the pixel defining layer PDL.

In an embodiment, the column spacer CS may include the same material as the inner wall IW. For example, the column spacer CS may include a light blocking material.

The reflective pattern RP may overlap the non-emissive area NEA. For example, the reflective pattern RP may overlap the pixel defining layer PDL.

In an embodiment, the reflective pattern RP may overlap the first outer wall OW1 and the inner wall IW. For example, the reflective pattern RP may be interposed between the first outer wall OW1 and the inner wall IW. Accordingly, the reflective pattern RP may contact the first outer wall OW1 and the inner wall IW. In addition, the reflective pattern RP may support the inner wall IW.

In an embodiment, the reflective pattern RP may further overlap the second outer wall OW2 and the inner wall IW. For example, the reflective pattern RP may be further interposed between the second outer wall OW2 and the inner wall IW. Accordingly, the reflective pattern RP may further contact the second outer wall OW2 and the inner wall IW. In addition, the reflective pattern RP may support the inner wall IW.

In an embodiment, the reflective pattern RP may be formed together with the inner wall IW. Accordingly, a boundary of the reflective pattern RP may coincide with a boundary of the inner wall IW.

In an embodiment, the reflective pattern RP may reflect light. For example, the reflective pattern RP may include metal, alloy, conductive metal oxide, etc. For example, the reflective pattern RP may include silver (Ag), an alloy containing silver, molybdenum (Mo), an alloy containing molybdenum, aluminum (Al), an alloy containing aluminum, aluminum nitride. (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The metal pattern MP may overlap the non-emission area NEA. For example, the metal pattern MP may overlap the third color conversion pattern CV3 and the column spacer CS, and may be disposed between the third color conversion pattern CV3 and the column spacer CS.

In an embodiment, the metal pattern MP may include the same material as the reflective pattern RP. For example, the metal pattern MP may include metal, alloy, conductive metal oxide, etc.

The first color conversion pattern CV1 may overlap the first emission area EA1. For example, the first color conversion pattern CV1 may overlap the first pixel electrode PXR.

In addition, the first color conversion pattern CV1 may be accommodated by the first outer wall OW1. In other words, the first outer wall OW1 may be arranged to surround the first color conversion pattern CV1. Accordingly, the first color conversion pattern CV1 may contact the first outer wall OW1, the reflective pattern RP, and the inner wall IW.

In an embodiment, the first color conversion pattern CV1 may include a first monomer MN1, first quantum dots QD1, and first scattering particles SP1.

The first quantum dots QD1 and the first scattering particles SP1 may be dispersed in the first monomer MN1. In an embodiment, the first monomer MN1 may include an epoxy-based monomer, an ester-based monomer, etc.

The first quantum dots QD1 may convert the color of incident light to red. For example, the first quantum dots QD1 may be a quantum dot, and may be selected from the group consisting of group II-VI compounds, group IV-VI compounds, group IV elements, group IV compounds, and combinations thereof.

The first scattering particles SP1 may scatter light. In an embodiment, the first scattering particles SP1 may include titanium dioxide (TiO₂) particles, zinc oxide (ZnO) particles, aluminum oxide (Al₂O₃) particles, silicon oxide (SiO₂) particles, hollow silica particles, etc.

The second color conversion pattern CV2 may overlap the second emission area EA2. For example, the second color conversion pattern CV2 may overlap the second pixel electrode PXG.

In addition, the second color conversion pattern CV2 may be accommodated by the second outer wall OW2. In other words, the second outer wall OW2 may be arranged to surround the second color conversion pattern CV2. Accordingly, the second color conversion pattern CV2 may contact the second outer wall OW2, the reflective pattern RP, and the inner wall IW.

In an embodiment, the second color conversion pattern CV2 may include a second monomer MN2, second quantum dots QD2, and second scattering particles SP2.

The second quantum dots QD2 and the second scattering particles SP2 may be dispersed in the second monomer MN2. In an embodiment, the second monomer MN2 may include an epoxy-based monomer, an ester-based monomer, etc.

The second quantum dot QD2 may convert the color of incident light to green. For example, the second quantum dot QD2 may be a quantum dot, and may be selected from the group consisting of group II-VI compounds, group IV-VI compounds, group IV elements, group IV compounds, and combinations thereof.

The second scattering particles SP2 may scatter light. In an embodiment, the second scattering particles SP2 may include titanium dioxide (TiO₂) particles, zinc oxide (ZnO) particles, aluminum oxide (Al₂O₃) particles, silicon oxide (SiO₂) particles, hollow silica particles, etc.

In an embodiment, the inner wall IW may have liquid-repellent properties. For example, the inner wall IW may include a fluorine-based liquid repellent. Alternatively, fluorine-based (CF4, etc.) plasma treatment may be performed on the inner wall IW. Accordingly, the first color conversion pattern CV1 and the second color conversion pattern CV2 may be stably accommodated.

However, the present invention is not limited thereto. In another embodiment, the first outer wall OW1 and the second outer wall OW2 may have liquid-repellent properties.

The second capping layer CAP2 may be disposed on the filler FM. The second capping layer CAP2 may fix the first to third color conversion patterns CV1, CV2, and CV3.

In an embodiment, the second capping layer CAP2 may include an inorganic material. For example, the second capping layer CAP2 may include silicon oxide, silicon nitride, titanium oxide, tantalum oxide, etc. In another embodiment, the second capping layer CAP2 may include an organic material.

The third capping layer CAP3 may be disposed on the first outer wall OW1, the second outer wall OW2, and the third color conversion pattern CV3. In an embodiment, the third capping layer CAP3 may include an inorganic material. For example, the third capping layer CAP3 may include silicon oxide, silicon nitride, titanium oxide, tantalum oxide, etc. In another embodiment, the third capping layer CAP3 may include an organic material.

The refractive layer LR may be disposed on the third capping layer CAP3. The refractive layer LR may include a material with a relatively low refractive index (or a material with a relatively high refractive index).

The first color filter CFR may overlap the first emission area EA1. In an embodiment, the first color filter CFR may transmit only light having a wavelength band corresponding to red. For example, the first color filter CFR may include an organic material in which red pigment (or, red dye) is dispersed.

The second color filter CFG may overlap the second emission area EA2. In an embodiment, the second color filter CFG may transmit only light having a wavelength band corresponding to green. For example, the second color filter CFG may include an organic material in which green pigment (or, green dye) is dispersed.

The third color filter CFB may overlap the third emission area EA3. In an embodiment, the third color filter CFB may transmit only light having a wavelength band corresponding to blue. For example, the third color filter CFB may include an organic material in which blue pigment (or, blue dye) is dispersed.

The upper substrate TSUB may be disposed on the first to third color filters CFR, CFG, and CFB. The upper substrate TSUB may include a transparent material or an opaque material. In an embodiment, examples of materials that can be used as the upper substrate TSUB may include glass, quartz, and plastic. These can be used alone or in combination with each other.

Referring to FIG. 7, the first outer wall OW1 may have a first width W1 in the first direction D1. For example, the first width W1 may be about 5 μm to 6 μm. The second outer wall OW2 may have the same first width W1 as the first outer wall OW1.

The inner wall IW may have a second width W2 and a third width W3 in the first direction D1. The second width W2 may be a width of the inner wall IW disposed between the first and second outer walls OW1 and OW2, and the third width W3 may be a width of the protruding inner wall IW. For example, the second width W2 may be about 3 μm to 4 μm, and the third width W3 may be about 4 μm to 5 μm.

In an embodiment, the first width W1 may be greater than the third width W3. Accordingly, the first outer wall OW1 and the second outer wall OW2 may support the inner wall IW.

The first outer wall OW1 may have a first thickness TH1 in the third direction D3. For example, the first thickness TH1 may be about 5 μm to 7 μm. The second outer wall OW2 may have the same first thickness TH1 as the first outer wall OW1.

The inner wall IW may have a second thickness TH2 in the third direction D3. For example, the second thickness TH2 may be about 9 μm to 10 μm.

In an embodiment, the second thickness TH2 may be greater than the first thickness TH1. Accordingly, the internal partition IW may prevent color mixing.

Referring to FIGS. 6 and 7, the display device DD1 according to an embodiment may include the color conversion substrate 2000. The color conversion substrate 2000 may include the first outer wall OW1, the second outer wall OW2, the reflective pattern RP, and the inner wall IW.

The first color conversion pattern CV1 may be accommodated in the first outer wall OW1, and the second color conversion pattern CV2 may be accommodated in the second outer wall OW2. The inner wall IW may be disposed between the first and second outer walls OW1 and OW2, and the reflective pattern RP may be interposed between the first outer wall OW1 (or, the second outer wall OW2) and the inner wall IW.

The first and second outer walls OW1 and OW2 may support the inner wall IW and may fix the inner wall IW. Accordingly, the reliability of the display device DD1 may be improved.

In addition, the first and second outer walls OW1 and OW2 may include scattering particles, and the reflective pattern RP may reflect light. Accordingly, the aperture ratio of the display device DD1 may be increased.

In addition, the inner wall IW may block light. Accordingly, the inner wall IW may suppress external light reflection and prevent color mixing. Accordingly, color reproducibility of the display device DD1 may be improved.

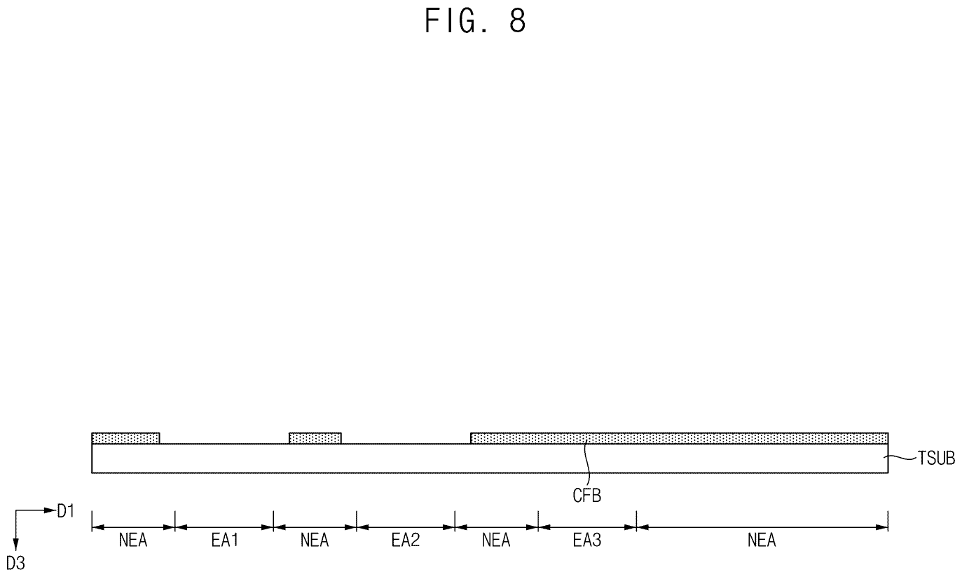

FIGS. 8 to 22 are diagrams illustrating a method of manufacturing the display device of FIG. 4.

Referring to FIG. 8, the third color filter CFB may be formed on the upper substrate TSUB. The third color filter CFB may overlap the third emission area EA3 and the non-emission area NEA, and may have an opening that overlaps the first and second emission areas EA1 and EA2.

For example, the third color filter CFB may be formed through a photolithography process using a first mask.

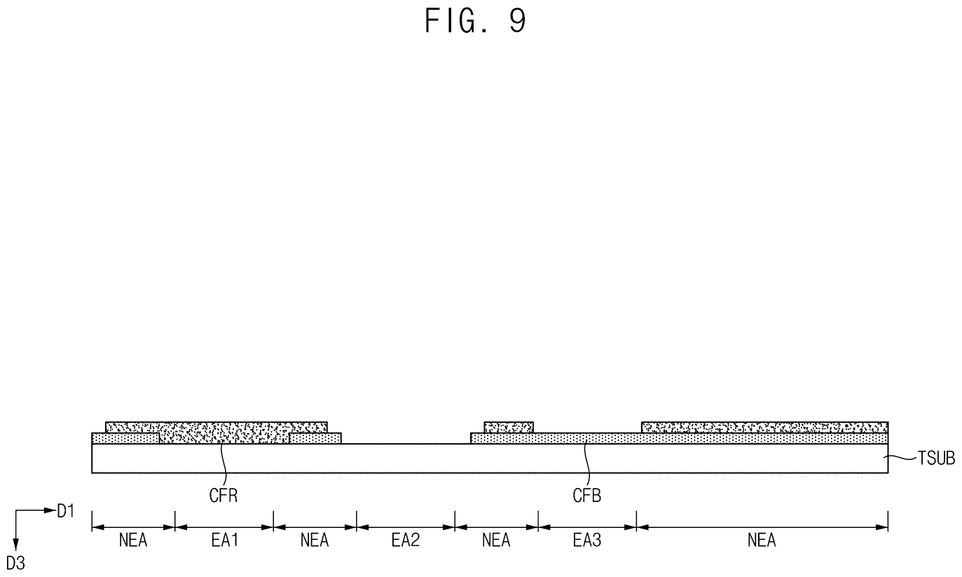

Referring to FIG. 9, the first color filter CFR may be formed on the upper substrate TSUB. The first color filter CFR may overlap the first emission area EA1 and the non-emission area NEA, and may have an opening that overlaps the second and third emission areas EA2 and EA3.

For example, the first color filter CFR may be formed through a photolithography process using a second mask.

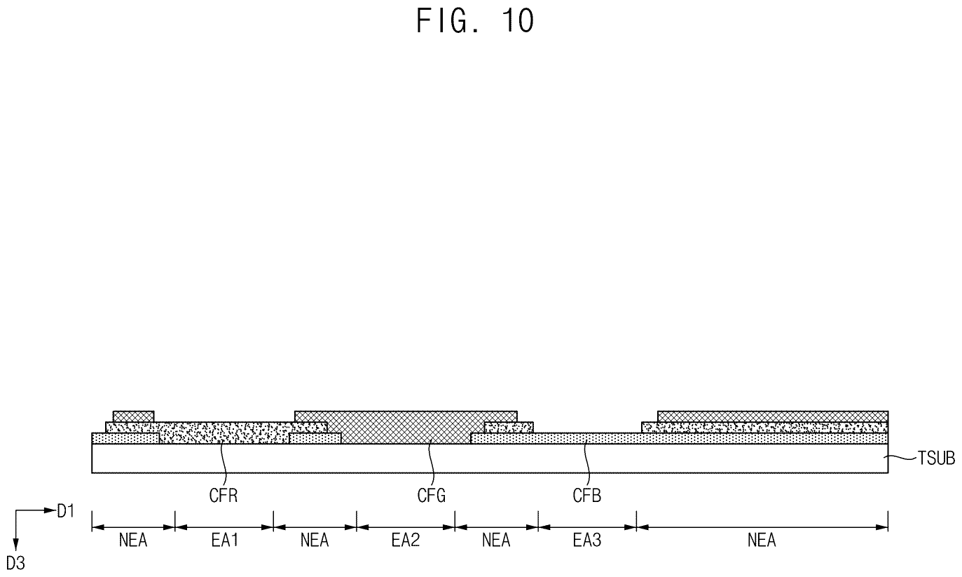

Referring to FIG. 10, the second color filter CFG may be formed on the upper substrate TSUB. The second color filter CFG may overlap the second emission area EA2 and the non-emission area NEA, and may have an opening that overlaps the first and third emission areas EA1 and EA3.

For example, the second color filter CFG may be formed through a photolithography process using a third mask.

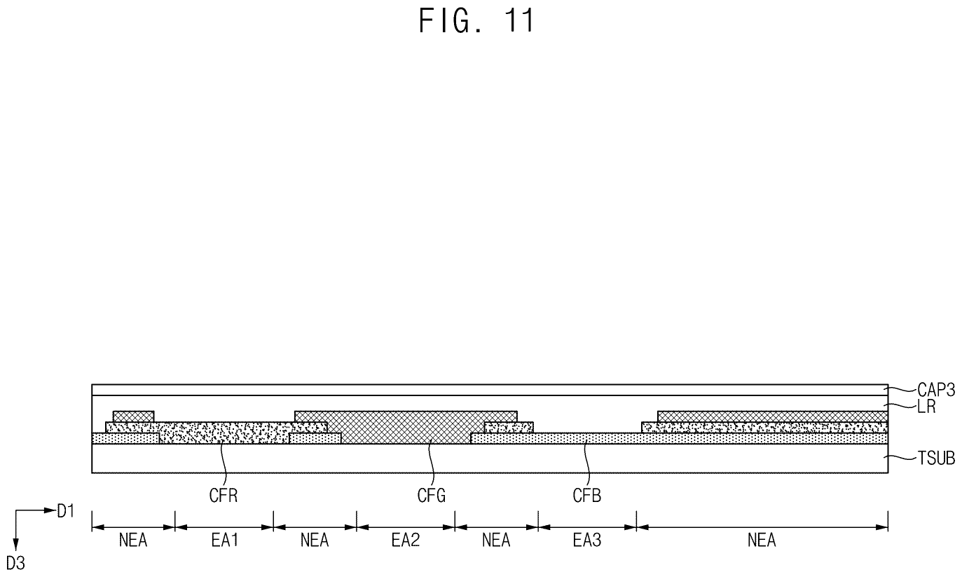

Referring to FIG. 11, the refractive layer LR and the third capping layer CAP3 may be formed sequentially.

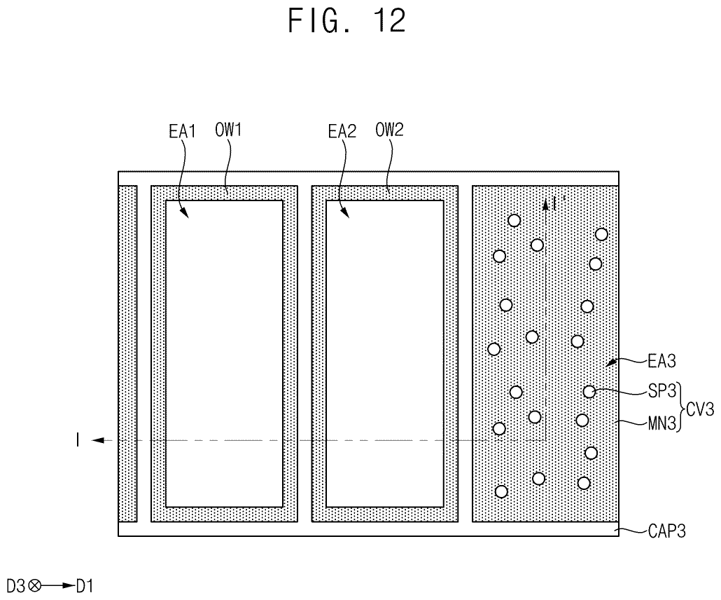

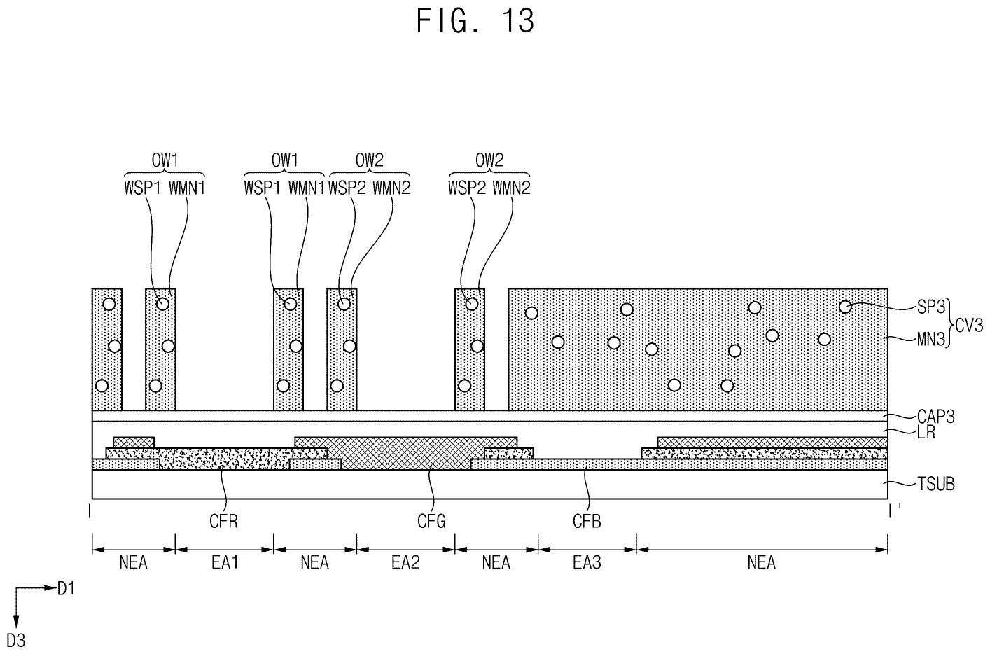

FIG. 13 is a cross-sectional view taken along a line I-I′ of FIG. 12.

Referring to FIGS. 12 and 13, the first outer wall OW1, the second outer wall OW2, and the third color conversion pattern CV3 may be formed on the third capping layer CAP3. The first outer wall OW1 may surround the first emission area EA1, the second outer wall OW2 may surround the second emission area EA2, and the third color conversion pattern CV3 may overlap the third emission area EA3.

In an embodiment, the first outer wall OW1, the second outer wall OW2, and the third color conversion pattern CV3 may be formed together. For example, the first outer wall OW1, the second outer wall OW2, and the third color conversion pattern CV3 may be formed through a photolithography process using a fourth mask.

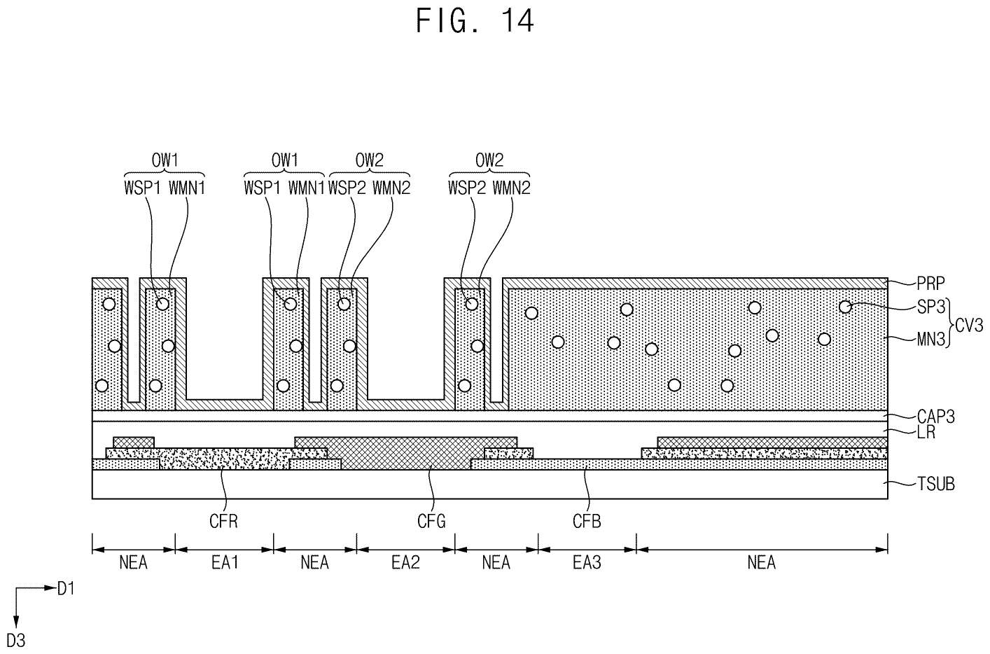

Referring to FIG. 14, a preliminary reflective pattern PRP may be formed. In an embodiment, the preliminary reflective pattern PRP may be entirely deposited. For example, the preliminary reflective pattern PRP may cover the first outer wall OW1, the second outer wall OW2, and the third color conversion pattern CV3.

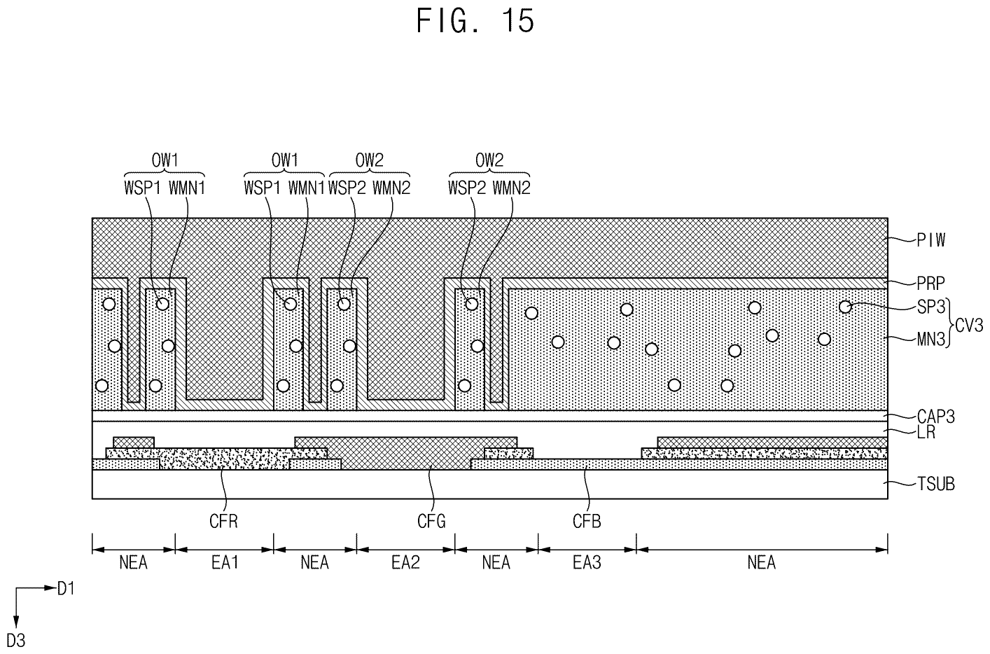

Referring to FIG. 15, a preliminary inner wall PIW may be formed. In an embodiment, the preliminary inner wall PIW may be formed entirely on the preliminary reflective pattern PRP.

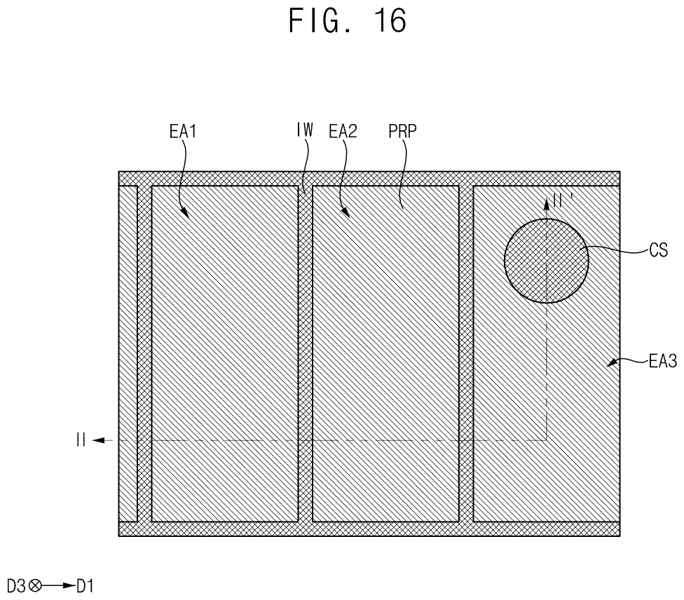

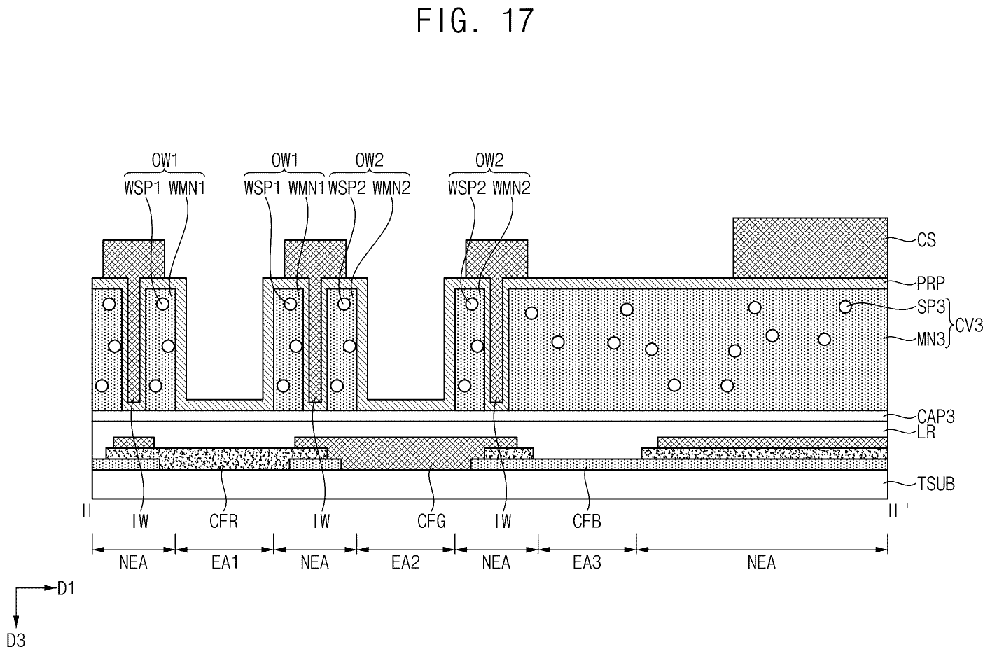

FIG. 17 is a cross-sectional view taken along a line II-II′ of FIG. 16.

Referring to FIGS. 16 and 17, the inner wall IW and the column spacer CS may be formed together. For example, the inner wall IW and the column spacer CS may be formed through a photolithography process using a fifth mask. In addition, accordingly, the preliminary reflective pattern PRP may be exposed in the first to third emission areas EA1, EA2, and EA3.

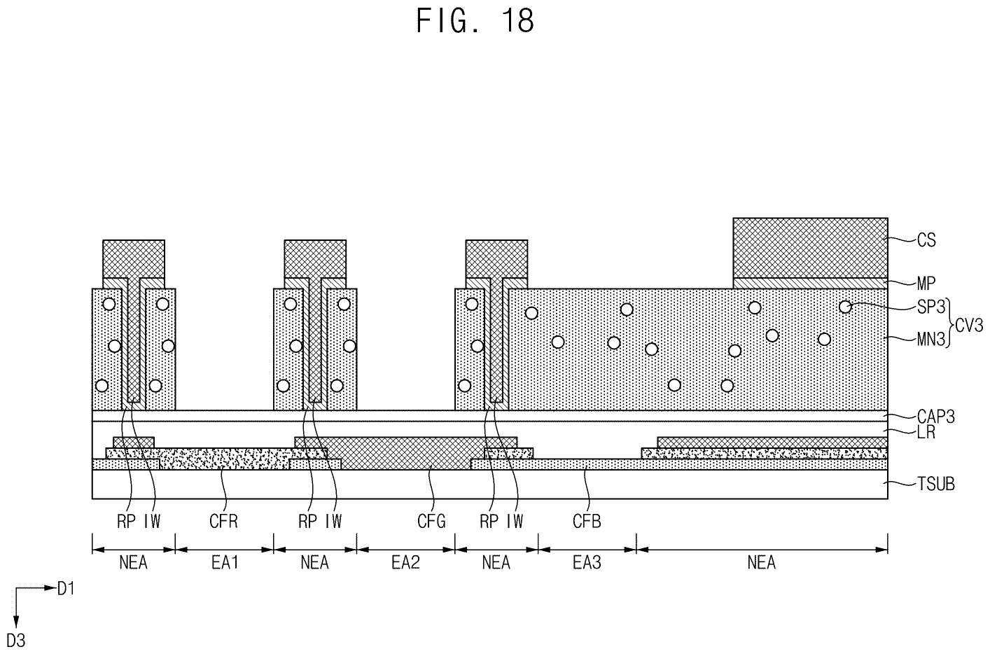

Referring to FIG. 18, the reflective pattern RP and the metal pattern MP may be formed. In an embodiment, the reflective pattern RP and the metal pattern MP may be etched using the inner wall IW and the column spacer CS as a mask. In other words, in the process of forming the reflective pattern RP and the metal pattern MP, an additional mask may not be required.

Accordingly, a boundary of the reflective pattern RP may substantially coincide with a boundary of the inner wall IW. In addition, a boundary of the metal pattern MP may substantially coincide with a boundary of the column spacer CS.

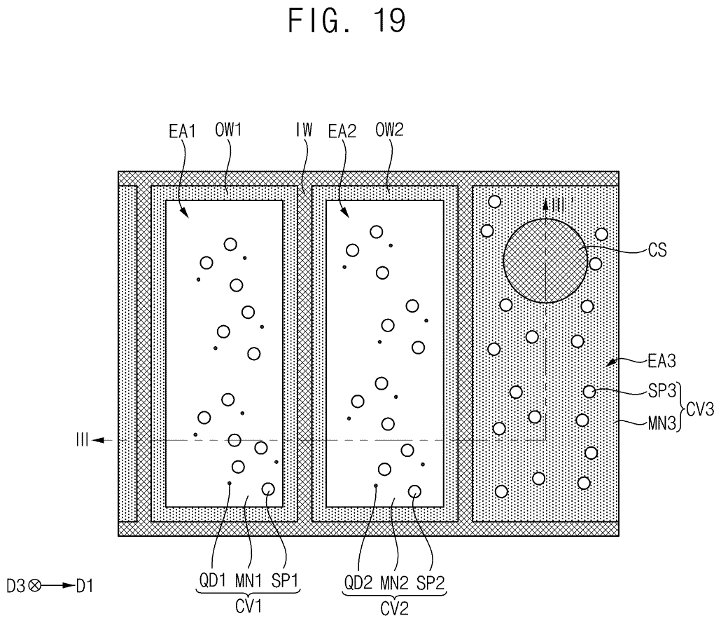

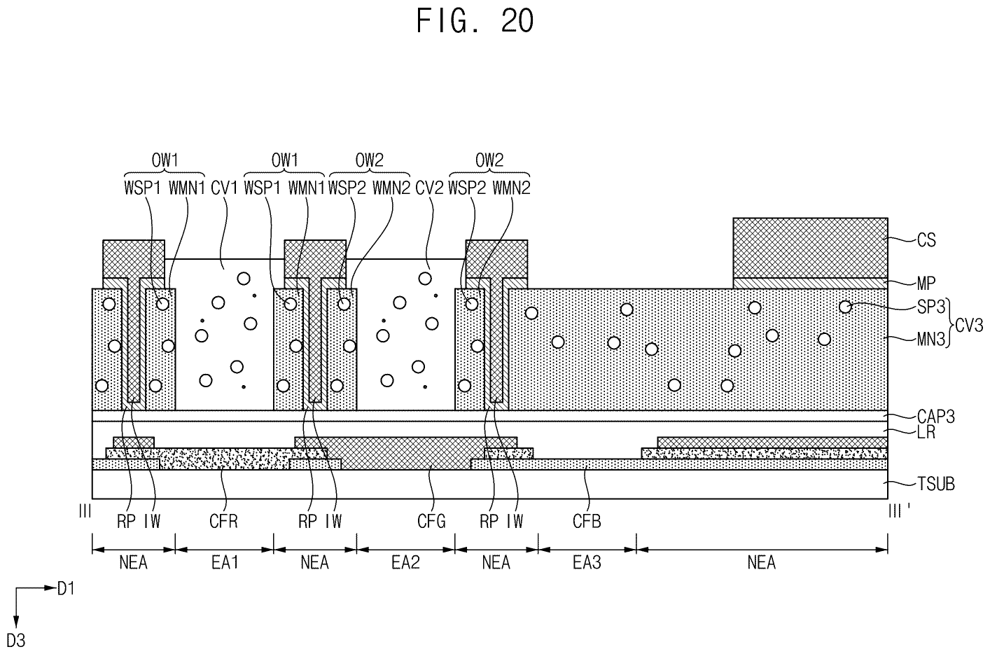

FIG. 20 is a cross-sectional view taken along a line III-III′ of FIG. 19.

Referring to FIGS. 19 and 20, the first color conversion pattern CV1 may be formed. The first color conversion pattern CV1 may be printed through an inkjet printing process and may be accommodated in the first outer wall OW1.

In addition, the second color conversion pattern CV2 may be formed. The second color conversion pattern CV2 may be printed through an inkjet printing process and may be accommodated in the second outer wall OW2.

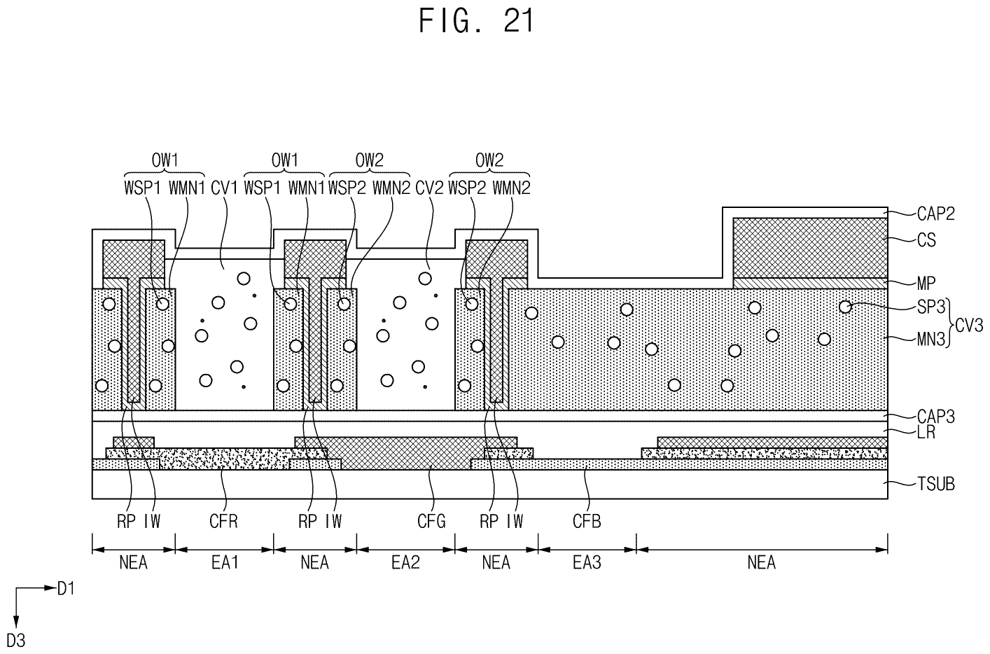

Referring to FIG. 21, the second capping layer CAP2 may be formed. The second capping layer CAP2 may cover the first to third color conversion patterns CV1, CV2, and CV3. Accordingly, the color conversion substrate 2000 may be manufactured.

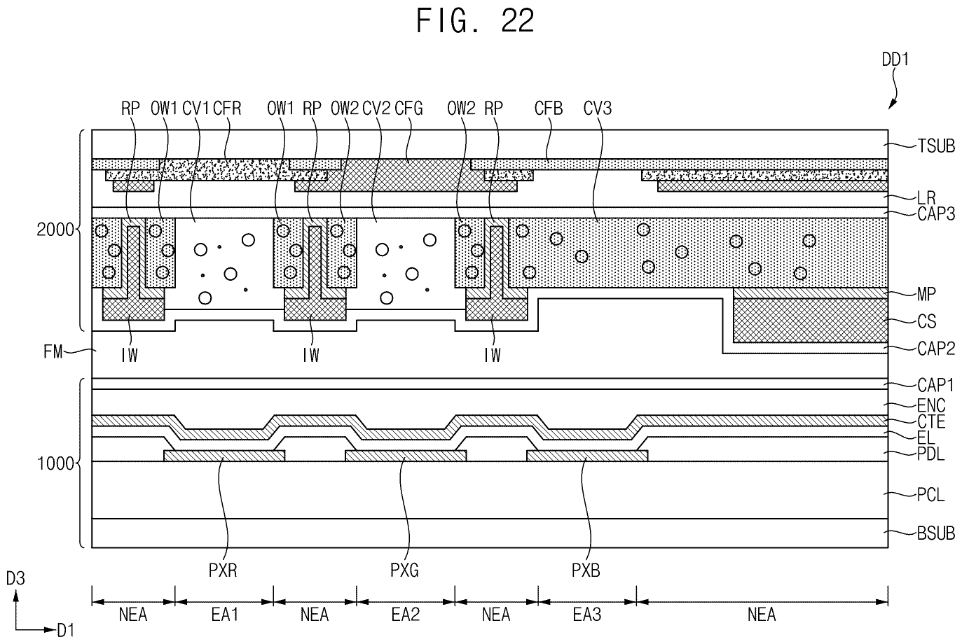

Referring to FIG. 22, the color conversion substrate 2000 may be coupled to the prepared emission substrate 1000. Accordingly, the display device DD1 may be manufactured.

In the method of manufacturing the display device DD1 according to an embodiment, the first outer wall OW1 and the second outer wall OW2 may be formed together with the third color conversion pattern CV3. Accordingly, in the process of forming the first outer wall OW1 and the second outer wall OW2, an additional mask may not be required.

In addition, by patterning the preliminary inner wall PIW, the inner wall IW and the column spacer CS may be formed together. Accordingly, in the process of forming the inner wall IW, an additional mask may not be required.

In addition, the reflective pattern RP and the metal pattern MP may be formed by using the inner wall IW and the column spacer CS as a mask. Accordingly, in the process of forming the reflective pattern RP and the metal pattern MP, an additional mask may not be required.

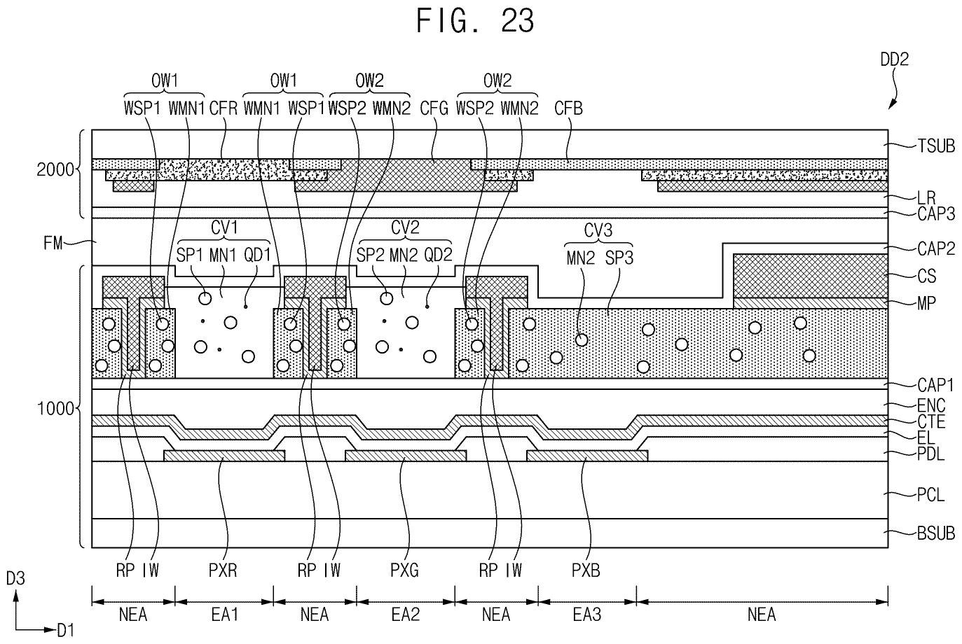

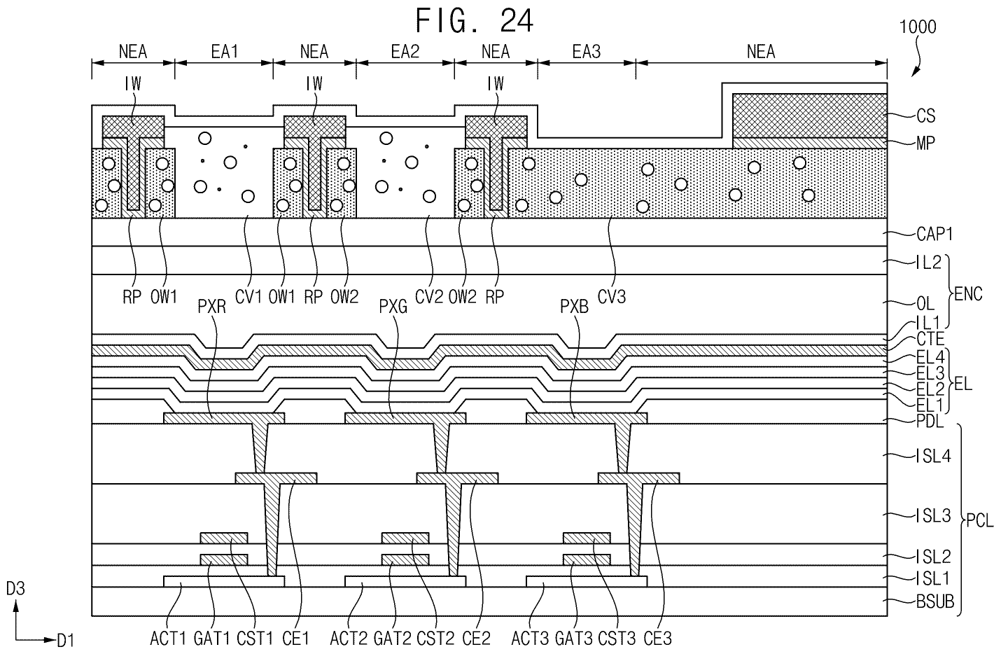

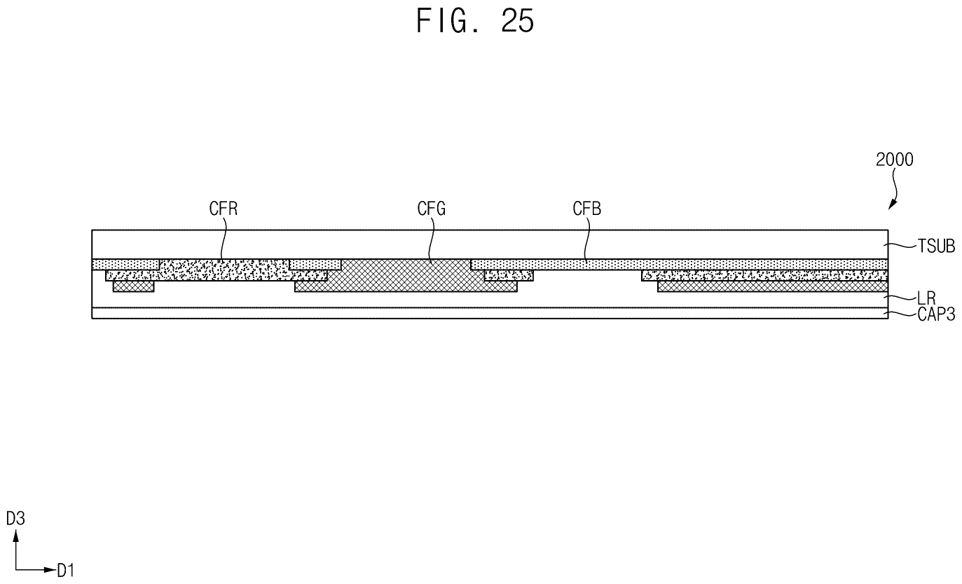

FIG. 23 is a cross-sectional view illustrating a display device according to an embodiment. FIG. 24 is a cross-sectional view illustrating an emission substrate included in the display device of FIG. 23. FIG. 25 is a cross-sectional view illustrating a color conversion substrate included in the display device of FIG. 23.

Referring to FIG. 23, a display device DD2 according to an embodiment may include an emission substrate 1000, a filler FM, and a color conversion substrate 2000.

The emission substrate 1000 may generate and emit light. In an embodiment, the emission substrate 1000 may include a pixel circuit layer PCL and an emission layer EL. The pixel circuit layer PCL may generate a driving current, and the emission layer EL may emit light based on the driving current.

The color conversion substrate 2000 may be disposed on the emission substrate 1000. In an embodiment, the color conversion substrate 2000 may convert the color of light emitted from the emission substrate 1000. Accordingly, color reproducibility of the display device DD2 may be improved.

The filler FM may be interposed between the emission substrate 1000 and the color conversion substrate 2000. In an embodiment, the filler FM may improve the reliability of the display device DD2 and refract light.

Referring to FIGS. 23 and 24, in an embodiment, the emission substrate 1000 may include a lower substrate BSUB, a pixel circuit layer PCL, a first pixel electrode PXR, a second pixel electrode PXG, a third pixel electrode PXB, a pixel defining layer PDL, an emission layer EL, a common electrode CTE, an encapsulation layer ENC, a first capping layer CAP1, a first outer wall OW1, a second outer wall OW2, a third color conversion pattern CV3, a reflective pattern RP, a metal pattern MP, an inner wall IW, a column spacer CS, a first color conversion pattern CV1, a second color conversion pattern CV2, and a second capping layer CAP2.

However, the emission substrate 1000 included in the display device DD2 may be substantially the same as the emission substrate 1000 described above with reference to FIG. 5, except for the first outer wall OW1, the second outer wall OW2, the third color conversion pattern CV3, the reflective pattern RP, the metal pattern MP, the inner wall IW, the column spacer CS, the first color conversion pattern CV1, the second color conversion pattern CV2, and the second capping layer CAP2.

The first outer wall OW1 may be disposed on the first capping layer CAP1 and may overlap the non-emission area NEA. For example, the first outer wall OW1 may overlap the pixel defining layer PDL. In addition, the first outer wall OW1 may be formed to surround the first emission area EA1.

In an embodiment, the first outer wall OW1 may include a first wall monomer WMN1 and first wall scattering particles WSP1. The first wall scattering particles WSP1 may be dispersed in the first wall monomer WMN1.

In an embodiment, the first wall monomer WMN1 may include an epoxy-based monomer, an ester-based monomer, etc.

The first wall scattering particles WSP1 may scatter light. In an embodiment, the first wall scattering particles WSP1 may include titanium dioxide (TiO₂) particles, zinc oxide (ZnO) particles, aluminum oxide (Al₂O₃) particles, silicon oxide (SiO₂) particles, hollow silica particles, etc.

The second outer wall OW2 may be disposed on the first capping layer CAP1 and may overlap the non-emission area NEA. For example, the second outer wall OW2 may overlap the pixel defining layer PDL. In addition, the second outer wall OW2 may be formed to surround the second emission area EA2.

In an embodiment, the second outer wall OW2 may include a second wall monomer WMN2 and second wall scattering particles WSP2. The second wall scattering particles WSP2 may be dispersed in the second wall monomer WMN2.

In an embodiment, the second wall monomer WMN2 may include an epoxy-based monomer, an ester-based monomer, etc.

The second wall scattering particles WSP2 may scatter light. In an embodiment, the second wall scattering particles WSP2 may include titanium dioxide (TiO₂) particles, zinc oxide (ZnO) particles, aluminum oxide (Al₂O₃) particles, silicon oxide (SiO₂) particles, hollow silica particles, etc.

In an embodiment, the second outer wall OW2 may be formed of the same material as the first outer wall OW1. In detail, the second wall monomer WMN2 may be the same material as the first wall monomer WMN1, and the second wall scattering particles WSP2 may be the same material as the first wall scattering particles WSP1.

The third color conversion pattern CV3 may be disposed on the first capping layer CAP1 and may overlap the third emission area EA3 and the non-emission area NEA. For example, the third color conversion pattern CV3 may overlap the third pixel electrode PXB and the pixel defining layer PDL.

In an embodiment, the third color conversion pattern CV3 may include a third monomer MN3 and third scattering particles SP3. The third scattering particles SP3 may be dispersed in the third monomer MN3.

In an embodiment, the third monomer MN3 may include an epoxy-based monomer, an ester-based monomer, etc.

The third scattering particles SP3 may scatter light. In an embodiment, the third scattering particles SP3 may include titanium dioxide (TiO₂) particles, zinc oxide (ZnO) particles, aluminum oxide (Al₂O₃) particles, silicon oxide (SiO₂) particles, hollow silica particles, etc.

In an embodiment, the first outer wall OW1 and the second outer wall OW2 may be formed of the same material as the third color conversion pattern CV3. In detail, the first wall monomer WMN1 and the second wall monomer WMN2 may be the same material as the third monomer MN3, and the first wall scattering particles WSP1 and the second wall scattering particle WSP2 may be the same material as the third scattering particles SP3.

In an embodiment, the first outer wall OW1 and the second outer wall OW2 may be formed together with the third color conversion pattern CV3. Accordingly, a thickness of the first outer wall OW1 and a thickness of the second outer wall OW2 may be substantially the same as a thickness of the third color conversion pattern CV3.

The inner wall IW may be disposed on the first capping layer CAP1 and may overlap the non-emission area NEA. For example, the inner wall IW may overlap the pixel defining layer PDL. In addition, the inner wall IW may be formed to surround the first emission area EA1 and the second emission area EA2.

In an embodiment, the inner wall IW may be interposed between the first outer wall OW1 and the second outer wall OW2. Accordingly, the first outer wall OW1 and the second outer wall OW2 may support the inner wall IW.

In an embodiment, the inner wall IW may include a light blocking material. For example, the inner wall IW may include a dye or pigment having light blocking properties. Accordingly, the inner wall IW may suppress external light reflection and prevent color mixing.

The column spacer CS may be disposed on the first capping layer CAP1 and may overlap the non-emission area NEA. For example, the column spacer CS may overlap the third color conversion pattern CV3 and the pixel defining layer PDL.

In an embodiment, the column spacer CS may include the same material as the inner wall IW. For example, the column spacer CS may include a light blocking material.

The reflective pattern RP may overlap the non-emissive area NEA. For example, the reflective pattern RP may overlap the pixel defining layer PDL.

In an embodiment, the reflective pattern RP may overlap the first outer wall OW1 and the inner wall IW. For example, the reflective pattern RP may be interposed between the first outer wall OW1 and the inner wall IW. Accordingly, the reflective pattern RP may contact the first outer wall OW1 and the inner wall IW. In addition, the reflective pattern RP may support the inner wall IW.

In an embodiment, the reflective pattern RP may be formed together with the inner wall IW. Accordingly, a boundary of the reflective pattern RP may coincide with a boundary of the inner wall IW.

In an embodiment, the reflective pattern RP may further overlap the second outer wall OW2 and the inner wall IW. For example, the reflective pattern RP may be further interposed between the second outer wall OW2 and the inner wall IW. Accordingly, the reflective pattern RP may further contact the second outer wall OW2 and the inner wall IW. In addition, the reflective pattern RP may support the inner wall IW.

In an embodiment, the reflective pattern RP may be formed together with the inner wall IW. Accordingly, a boundary of the reflective pattern RP may coincide with a boundary of the inner wall IW.

In an embodiment, the reflective pattern RP may reflect light. For example, the reflective pattern RP may include metal, alloy, conductive metal oxide, etc. For example, the reflection pattern RP may include silver (Ag), an alloy containing silver, molybdenum (Mo), an alloy containing molybdenum, aluminum (Al), an alloy containing aluminum, aluminum nitride. (AlN), tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), etc.

The metal pattern MP may overlap the non-emission area NEA. For example, the metal pattern MP may overlap the third color conversion pattern CV3 and the column spacer CS, and may be located between the third color conversion pattern CV3 and the column spacer CS.

In an embodiment, the metal pattern MP may include the same material as the reflective pattern RP. For example, the metal pattern MP may include metal, alloy, conductive metal oxide, etc.

The first color conversion pattern CV1 may be disposed on the first capping layer CAP1 and may overlap the first emission area EA1. For example, the first color conversion pattern CV1 may overlap the first pixel electrode PXR.

In addition, the first color conversion pattern CV1 may be accommodated by the first outer wall OW1. In other words, the first outer wall OW1 may be arranged to surround the first color conversion pattern CV1. Accordingly, the first color conversion pattern CV1 may contact the first outer wall OW1, the reflective pattern RP, and the inner wall IW.

In an embodiment, the first color conversion pattern CV1 may include a first monomer MN1, first quantum dots QD1, and first scattering particles SP1.

The first quantum dots QD1 and the first scattering particles SP1 may be dispersed in the first monomer MN1. In an embodiment, the first monomer MN1 may include an epoxy-based monomer, an ester-based monomer, etc.

The first quantum dots QD1 may convert the color of incident light to red. For example, the first quantum dots QD1 may be a quantum dot, and may be selected from the group consisting of group II-VI compounds, group IV-VI compounds, group IV elements, group IV compounds, and combinations thereof.

The first scattering particles SP1 may scatter light. In an embodiment, the first scattering particles SP1 may include titanium dioxide (TiO₂) particles, zinc oxide (ZnO) particles, aluminum oxide (Al₂O₃) particles, silicon oxide (SiO₂) particles, hollow silica particles, etc.

The second color conversion pattern CV2 may be disposed on the first capping layer CAP1 and may overlap the second emission area EA2. For example, the second color conversion pattern CV2 may overlap the second pixel electrode PXG.

In addition, the second color conversion pattern CV2 may be accommodated by the second outer wall OW2. In other words, the second outer wall OW2 may be arranged to surround the second color conversion pattern CV2. Accordingly, the second color conversion pattern CV2 may contact the second outer wall OW2, the reflective pattern RP, and the inner wall IW.

In an embodiment, the second color conversion pattern CV2 may include a second monomer MN2, second quantum dots QD2, and second scattering particles SP2.

The second quantum dots QD2 and the second scattering particles SP2 may be dispersed in the second monomer MN2. In an embodiment, the second monomer MN2 may include an epoxy-based monomer, an ester-based monomer, etc.

The second quantum dots QD2 may convert the color of incident light to green. For example, the second quantum dots QD2 may be a quantum dot, and may be selected from the group consisting of group II-VI compounds, group IV-VI compounds, group IV elements, group IV compounds, and combinations thereof.

The second scattering particles SP2 may scatter light. In an embodiment, the second scattering particles SP2 may include titanium dioxide (TiO₂) particles, zinc oxide (ZnO) particles, aluminum oxide (Al₂O₃) particles, silicon oxide (SiO₂) particles, hollow silica particles, etc.

In an embodiment, the inner wall IW may have liquid-repellent properties. For example, the inner wall IW may include a fluorine-based liquid repellent. Alternatively, fluorine-based (CF4, etc.) plasma treatment may be performed on the inner wall IW. Accordingly, the first color conversion pattern CV1 and the second color conversion pattern CV2 may be stably accommodated.

However, the first outer wall OW1 and the second outer wall OW2 are not limited thereto. In another embodiment, the first outer wall OW1 and the second outer wall OW2 may have liquid-repellent properties.

The second capping layer CAP2 may be disposed on the inner wall IW and the column spacer CS, and may fix the first to third color conversion patterns CV1, CV2, and CV3.

In an embodiment, the second capping layer CAP2 may include an inorganic material. For example, the second capping layer CAP2 may include silicon oxide, silicon nitride, titanium oxide, tantalum oxide, etc. In another embodiment, the second capping layer CAP2 may include an organic material.

The filler FM may be disposed on the second capping layer CAP2. In an embodiment, the filler FM may include an organic material such as urethane-based resin, epoxy-based resin, or acrylic resin.

Referring to FIGS. 23 and 25, the color conversion substrate 2000 may include an upper substrate TSUB, a first color filter CFR, a second color filter CFG, a third color filter CFB, a refractive layer LR, and a third capping layer CAP3.

However, the upper substrate TSUB, the first color filter CFR, the second color filter CFG, the third color filter CFB, the refractive layer LR, and the third capping layer CAP3 may be substantially the same as the upper substrate TSUB, the first color filter CFR, the second color filter CFG, the third color filter CFB, the refractive layer LR, and the third capping layer CAP3 described with reference to FIG. 6.

The display device DD1, DD2 according to embodiments may be applied to various electronic devices. An electronic device according to an embodiment may include the display device DD1, DD2 described above, and may further include a module or device having additional functions in addition to the display device DD1, DD2.

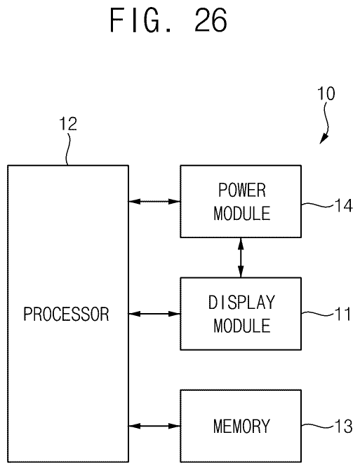

FIG. 26 is a block diagram illustrating an electronic device according to an embodiment.

Referring to FIG. 26, an electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter, a battery device, or the like and a power conversion module that converts power supplied by the power supply module to generate power necessary for an operation of the electronic device 10.

At least one of the components of the electronic device 10 described above may be included in the display device according to embodiments described above. In addition, some of individual modules functionally included in one module may be included in the display device, and others may be provided separately from the display device. For example, the display device may include the display module 11, and the processor 12, the memory 13, and the power module 14 may be provided in form of other devices in the electronic device 10 other than the display device.

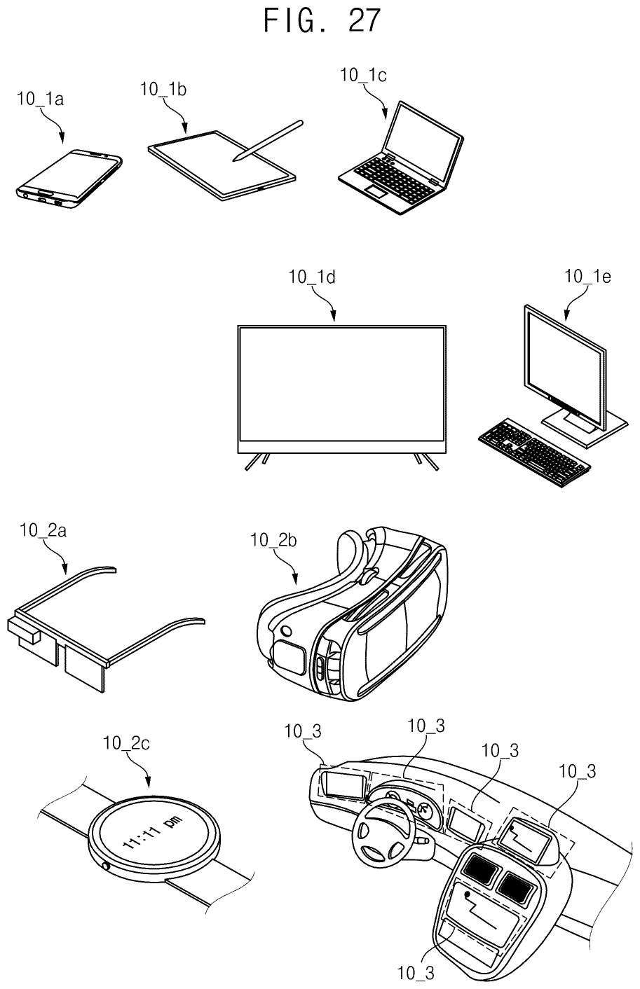

FIG. 27 is a schematic diagram of electronic devices.

Referring to FIG. 27, various electronic devices to which the display device according to embodiments are applied may include not only an image display electronic device, but also a wearable electronic device including a display module, a vehicle electronic device 10_3 including a display module, or the like. The image display electronic device may be a smartphone 10_1a, a tablet PC 10_1b, a laptop 10_1c, a TV 10_1d, a desk monitor 10_1e, or the like. The wearable electronic device may be smart glasses 10_2a, a head mounted display 10_2b, a smart watch 10_2c, or the like. The vehicle electronic device 10_3 may be a center information display (CID) disposed on a dashboard and center fascia of a vehicle, a room mirror display, or the like.

Although embodiments have been described herein, other embodiments and modifications will be apparent from this description. Accordingly, the inventive concepts are not limited to such embodiments, but rather to the broader scope of the appended claims and various modifications and equivalent arrangements as would be apparent to a person of ordinary skill in the art.

What is claimed is:

1. A color conversion substrate comprising:
an upper substrate divided into a first emission area, a second emission area adjacent to the first emission area, and a non-emission area located between the first emission area and the second emission area;
a first color conversion pattern disposed on the upper substrate and overlapping the first emission area;
a second color conversion pattern disposed on the upper substrate and overlapping the second emission area;
a first outer wall accommodating the first color conversion pattern, overlapping the non-emission area, and including scattering particles;
a second outer wall accommodating the second color conversion pattern, overlapping the non-emission area, and including the scattering particles; and
an inner wall interposed between the first outer wall and the second outer wall.

2. The color conversion substrate of claim 1, wherein the first outer wall and the second outer wall scatter light, and
wherein the inner wall blocks light.

3. The color conversion substrate of claim 1, wherein the first outer wall and the second outer wall support the inner wall.

4. The color conversion substrate of claim 1, wherein the inner wall overlaps the non-emission area.

5. The color conversion substrate of claim 1, further comprising:
a third color conversion pattern disposed on the upper substrate, overlapping a third emission area adjacent to the second emission area, and including the scattering particles.

6. The color conversion substrate of claim 5, wherein the first outer wall and the second outer wall include a same material as the third color conversion pattern.

7. The color conversion substrate of claim 5, further comprising:
a column spacer disposed on the third color conversion pattern and including a same material as the inner wall.

8. The color conversion substrate of claim 1, further comprising:
a reflective pattern interposed between the first outer wall and the inner wall.

9. The color conversion substrate of claim 8, wherein the reflective pattern contacts the first outer wall and the inner wall.

10. The color conversion substrate of claim 8, wherein a boundary of the reflective pattern coincides with a boundary of the inner wall.

11. The color conversion substrate of claim 8, wherein the reflective pattern reflects light.

12. The color conversion substrate of claim 11, wherein the reflective pattern includes metal.

13. The color conversion substrate of claim 8, wherein the reflective pattern supports the inner wall.

14. The color conversion substrate of claim 8, wherein the reflective pattern is further interposed between the second outer wall and the inner wall.

15. A display device comprising:
a lower substrate divided into a first emission area, a second emission area adjacent to the first emission area, and a non-emission area located between the first emission area and the second emission area;
a first color conversion pattern disposed on the lower substrate and overlapping the first emission area;
a second color conversion pattern disposed on the lower substrate and overlapping the second emission area;
a first outer wall accommodating the first color conversion pattern, overlapping the non-emission area, and including scattering particles;
a second outer wall accommodating the second color conversion pattern, overlapping the non-emission area, and including the scattering particles; and
an inner wall interposed between the first outer wall and the second outer wall.

16. The display device of claim 15, further comprising:
a first pixel electrode disposed between the lower substrate and the first color conversion pattern and overlapping the first color conversion pattern;
a second pixel electrode disposed between the lower substrate and the second color conversion pattern and overlapping the second color conversion pattern; and
an emission layer disposed on the first pixel electrode and the second pixel electrode.

17. The display device of claim 15, further comprising:
a pixel defining layer disposed between the lower substrate and the inner wall and overlapping the inner wall.

18. The display device of claim 15, wherein the first outer wall and the second outer wall scatter light, and
wherein the inner wall blocks light.

19. The display device of claim 15, wherein the first outer wall and the second outer wall support the inner wall.

20. The display device of claim 15, wherein the inner wall overlaps the non-emission area.

21. The display device of claim 15, further comprising:
a third color conversion pattern disposed on the lower substrate, overlapping a third emission area adjacent to the second emission area, and including the scattering particles.

22. The display device of claim 21, wherein the first outer wall and the second outer wall include a same material as the third color conversion pattern.

23. The display device of claim 21, further comprising:
a column spacer disposed on the third color conversion pattern and including a same material as the inner wall.

24. The display device of claim 15, further comprising:
a reflective pattern interposed between the first outer wall and the inner wall.

25. The display device of claim 24, wherein the reflective pattern contacts the first outer wall and the inner wall.

26. The display device of claim 24, wherein a boundary of the reflective pattern coincides with a boundary of the inner wall.

27. The display device of claim 24, wherein the reflective pattern reflects light.

28. The display device of claim 27, wherein the reflective pattern includes metal.

29. The display device of claim 24, wherein the reflective pattern supports the inner wall.

30. The display device of claim 24, wherein the reflective pattern is further interposed between the second outer wall and the inner wall.

31. A method of manufacturing a display device, the method comprising:
providing an upper substrate divided into a first emission area, a second emission area adjacent to the first emission area, and a non-emission area located between the first emission area and the second emission area;
forming a first outer wall on the upper substrate, the first outer wall overlaps the non-emission area and including scattering particles;
forming a second outer wall on the upper substrate, the second outer wall overlaps the non-emission area and including the scattering particles;
forming an inner wall interposed between the first outer wall and the second outer wall;
forming a first conversion pattern accommodated in the first outer wall and overlapping the first emission area; and
forming a second conversion pattern accommodated in the second outer wall and overlapping the second emission area.

32. The method of claim 31, wherein the first outer wall and the second outer wall are formed together.

33. The method of claim 31, further comprising:
forming a third color conversion pattern on the upper substrate,
wherein the third color conversion pattern overlaps a third emission area adjacent to the second emission area and including the scattering particles.

34. The method of claim 33, wherein the first outer wall, the second outer wall, and the third color conversion pattern are formed together.

35. The method of claim 33, further comprising:
forming a column spacer on the third color conversion pattern, wherein the column spacer includes a same material as the inner wall.

36. The method of claim 35, wherein the inner wall and the column spacer are formed together.

37. The method of claim 31, further comprising:
forming a reflective pattern interposed between the first outer wall and the inner wall.

38. The method of claim 37, wherein the reflective pattern contacts the first outer wall and the inner wall.

39. The method of claim 37, wherein the forming the reflective pattern includes:
forming a preliminary reflective pattern covering the first outer wall; and
etching the preliminary reflective pattern using the inner wall as a mask.

40. An electronic device comprising:
a display device; and
a power supply configured to provide power to the display device,
wherein the display device comprises:
a lower substrate divided into a first emission area, a second emission area adjacent to the first emission area, and a non-emission area located between the first emission area and the second emission area;
a first color conversion pattern disposed on the lower substrate and overlapping the first emission area;
a second color conversion pattern disposed on the lower substrate and overlapping the second emission area;
a first outer wall accommodating the first color conversion pattern, overlapping the non-emission area, and including scattering particles;
a second outer wall accommodating the second color conversion pattern, overlapping the non-emission area, and including the scattering particles; and
an inner wall interposed between the first outer wall and the second outer wall.
